(19) United States
(12) Patent Application Publication
(10) Pub. No.: US 2016/0093569 A1
(43) Pub. Date: Mar. 31, 2016

(54) SEMICONDUCTOR DEVICE AND METHOD FOR MANUFACTURING THE SAME

(71) Applicant: KABUSHIKI KAISHA TOSHIBA, Minato-ku (JP)

(72) Inventors: Kotaro FUJII, Yokkaichi (JP); Maki Miyazaki, Yokkaichi (JP)

(73) Assignee: KABUSHIKI KAISHA TOSHIBA, Minato-ku (JP)

(21) Appl. No.: 14/687,337

(22) Filed: Apr. 15, 2015

(30) Foreign Application Priority Data
Sep. 30, 2014 (JP) 2014-202636

(51) Int. Cl. H01L 23/522; H01L 21/768

(52) U.S. Cl. CPC H01L 23/5226; H01L 21/76816

(57) ABSTRACT

A semiconductor device includes a base body, an insulating layer, first contacts and a first wiring. The insulating layer is disposed above the base body. The first contacts are disposed in the insulating layer. The first contacts are in contact with the base body. The first wiring is disposed around the first contacts. The first wiring has a lower height than the first contacts have. The first wiring includes convex portions in a part of a bottom portion thereof.

### CROSS-REFERENCE TO RELATED APPLICATION(S)

This application is based upon and claims the benefit of priority from Japanese Patent Application No. 2014-202636, filed on Sep. 30, 2014, the entire contents of which are incorporated herein by reference.

### FIELD

Embodiments described herein relate generally to a semiconductor device and a method for manufacturing the same.

### BACKGROUND

Recently, diameters of contact holes have been reduced in accordance with shrinkage of semiconductor devices. The reduction in size has led to increase in difficulty in mask pattern formation using a lithography method and etching process.

A micro-loading effect in which an etching rate changes in accordance with the density of a pattern to be processed has been known in etching process. Due to synergy between the development of shrinkage and the micro-loading effect, it gets more and more difficult to process contact holes.

### BRIEF DESCRIPTION OF THE DRAWINGS

FIG. 1 is a block diagram showing the configuration of a semiconductor device according to a first embodiment;

FIG. 2 is a schematic plan view of the semiconductor device according to the first embodiment;

FIG. 3 is a schematic electric configuration diagram showing a memory cell array and a sense amplifier portion in the semiconductor device according to the first embodiment;

FIG. 4 is a schematic plan view showing the memory cell array of the semiconductor device according to the first embodiment;

FIG. 5A is a schematic plan view showing a sparse contact hole formation portion of the semiconductor device according to the first embodiment;

FIG. 5B is a schematic sectional view taken along a line A-A in FIG. 5A showing the sparse contact hole formation portion of the semiconductor device according to the first embodiment;

FIG. 5C is a schematic plan view showing a dense contact hole formation portion of the semiconductor device according to the first embodiment;

FIG. 5D is a schematic sectional view taken along a line B-B in FIG. 5C showing the dense contact hole formation portion of the semiconductor device according to the first embodiment;

FIG. 6A is a schematic plan view showing a manufacturing process (part 1) according to the first embodiment;

FIG. 6B is a schematic sectional view taken along line a A-A in FIG. 6A showing the manufacturing process (part 1) according to the first embodiment;

FIG. 6C is another schematic plan view showing the manufacturing process (part 1) according to the first embodiment;

FIG. 6D is another schematic sectional view taken along a line B-B in FIG. 6C showing the manufacturing process (part 1) according to the first embodiment;

FIG. 7A is a schematic plan view showing the manufacturing process (part 2) according to the first embodiment;

FIG. 7B is a schematic sectional view taken along a line A-A in FIG. 7A showing the manufacturing process (part 2) according to the first embodiment;

FIG. 7C is another schematic plan view showing the manufacturing process (part 2) according to the first embodiment;

FIG. 7D is another schematic sectional view taken along a line B-B in FIG. 7C showing the manufacturing process (part 2) according to the first embodiment;

FIG. 8A is a schematic plan view showing the manufacturing process (part 3) according to the first embodiment;

FIG. 8B is a schematic sectional view taken along a line A-A in FIG. 8A showing the manufacturing process (part 3) according to the first embodiment;

FIG. 8C is another schematic plan view showing the manufacturing process (part 3) according to the first embodiment;

FIG. 8D is another schematic sectional view taken along a line B-B in FIG. 8C showing the manufacturing process (part 3) according to the first embodiment;

FIG. 9A is a schematic plan view showing the manufacturing process (part 4) according to the first embodiment;

FIG. 9B is a schematic sectional view taken along a line A-A in FIG. 9A showing the manufacturing process (part 4) according to the first embodiment;

FIG. 9C is another schematic plan view showing the manufacturing process (part 4) according to the first embodiment;

FIG. 9D is another schematic sectional view taken along a line B-B in FIG. 9C showing the manufacturing process (part 4) according to the first embodiment;

FIG. 10A is a schematic plan view showing the manufacturing process (part 5) according to the first embodiment;

FIG. 10B is a schematic sectional view taken along a line A-A in FIG. 10A showing the manufacturing process (part 5) according to the first embodiment;

FIG. 10C is another schematic plan view showing the manufacturing process (part 5) according to the first embodiment;

FIG. 10D is another schematic sectional view taken along a line B-B in FIG. 10C showing the manufacturing process (part 5) according to the first embodiment;

FIG. 11A is a schematic plan view showing the manufacturing process (part 6) according to the first embodiment;

FIG. 11B is a schematic sectional view taken along a line A-A in FIG. 11A showing the manufacturing process (part 6) according to the first embodiment;

FIG. 11C is another schematic plan view showing the manufacturing process (part 6) according to the first embodiment;

FIG. 11D is another schematic sectional view taken along a line B-B in FIG. 11C showing the manufacturing process (part 6) according to the first embodiment;

FIG. 12A is a schematic plan view showing the manufacturing process (part 7) according to the first embodiment;

FIG. 12B is a schematic sectional view taken along a line A-A in FIG. 12A showing the manufacturing process (part 7) according to the first embodiment;

FIG. 12C is another schematic plan view showing the manufacturing process (part 7) according to the first embodiment;

FIG. 12D is another schematic sectional view taken along a line B-B in FIG. 12C showing the manufacturing process (part 7) according to the first embodiment;

FIG. 13A is a schematic plan view showing the manufacturing process (part 8) according to the first embodiment;

FIG. 13B is a schematic sectional view taken along a line A-A in FIG. 13A showing the manufacturing process (part 8) according to the first embodiment;

FIG. 13C is another schematic plan view showing the manufacturing process (part 8) according to the first embodiment;

FIG. 13D is another schematic sectional view taken along a line B-B in FIG. 13C showing the manufacturing process (part 8) according to the first embodiment;

FIG. 14A is a schematic plan view showing a sparse contact hole formation portion of a semiconductor device according to a second embodiment;

FIG. 14B is a schematic sectional view taken along a line A-A in FIG. 14A showing the sparse contact hole formation portion of the semiconductor device according to the second embodiment;

FIG. 14C is a schematic plan view showing a dense contact hole formation portion of the semiconductor device according to the second embodiment;

FIG. 14D is a schematic sectional view taken along a line B-B in FIG. 14C showing the dense contact hole formation portion of the semiconductor device according to the second embodiment;

FIG. 15A is a schematic plan view showing a manufacturing process (part 1) according to the second embodiment;

FIG. 15B is a schematic sectional view taken along a line A-A in FIG. 15A showing the manufacturing process (part 1) according to the second embodiment;

FIG. 15C is another schematic plan view showing the manufacturing process (part 1) according to the second embodiment;

FIG. 15D is another schematic sectional view taken along a line B-B in FIG. 15C showing the manufacturing process (part 1) according to the second embodiment;

FIG. 16A is a schematic plan view showing the manufacturing process (part 2) according to the second embodiment;

FIG. 16B is a schematic sectional view taken along a line A-A in FIG. 16A showing the manufacturing process (part 2) according to the second embodiment;

FIG. 16C is another schematic plan view showing the manufacturing process (part 2) according to the second embodiment;

FIG. 16D is another schematic sectional view taken along a line B-B in FIG. 16C showing the manufacturing process (part 2) according to the second embodiment;

FIG. 17A is a schematic plan view showing the manufacturing process (part 3) according to the second embodiment;

FIG. 17B is a schematic sectional view taken along a line A-A in FIG. 17A showing the manufacturing process (part 3) according to the second embodiment;

FIG. 17C is another schematic plan view showing the manufacturing process (part 3) according to the second embodiment;

FIG. 17D is another schematic sectional view taken along a line B-B in FIG. 17C showing the manufacturing process (part 3) according to the second embodiment;

FIG. 18A is a schematic plan view showing the manufacturing process (part 4) according to the second embodiment;

FIG. 18B is a schematic sectional view taken along a line A-A in FIG. 18A showing the manufacturing process (part 4) according to the second embodiment;

FIG. 18C is another schematic plan view showing the manufacturing process (part 4) according to the second embodiment;

FIG. 18D is another schematic sectional view taken along a line B-B in FIG. 18C showing the manufacturing process (part 4) according to the second embodiment;

FIG. 19A is a schematic plan view showing the manufacturing process (part 5) according to the second embodiment;

FIG. 19B is a schematic sectional view taken along a line A-A in FIG. 19A showing the manufacturing process (part 5) according to the second embodiment;

FIG. 19C is another schematic plan view showing the manufacturing process (part 5) according to the second embodiment;

FIG. 19D is another schematic sectional view taken along a line B-B in FIG. 19C showing the manufacturing process (part 5) according to the second embodiment;

FIG. 20A is a schematic plan view showing the manufacturing process (part 6) according to the second embodiment;

FIG. 20B is a schematic sectional view taken along a line A-A in FIG. 20A showing the manufacturing process (part 6) according to the second embodiment;

FIG. 20C is another schematic plan view showing the manufacturing process (part 6) according to the second embodiment;

FIG. 20D is another schematic sectional view taken along a line B-B in FIG. 20C showing the manufacturing process (part 6) according to the second embodiment;

FIG. 21A is a schematic plan view showing the manufacturing process (part 7) according to the second embodiment;

FIG. 21B is a schematic sectional view taken along a line A-A in FIG. 21A showing the manufacturing process (part 7) according to the second embodiment;

FIG. 21C is another schematic plan view showing the manufacturing process (part 7) according to the second embodiment;

FIG. 21D is another schematic sectional view taken along a line B-B in FIG. 21C showing the manufacturing process (part 7) according to the second embodiment;

FIG. 22A is a schematic plan view showing the manufacturing process (part 8) according to the second embodiment;

FIG. 22B is a schematic sectional view taken along a line A-A in FIG. 22A showing the manufacturing process (part 8) according to the second embodiment;

FIG. 22C is another schematic plan view showing the manufacturing process (part 8) according to the second embodiment; and

FIG. 22D is another schematic sectional view taken along a line B-B in FIG. 22C showing the manufacturing process (part 8) according to the second embodiment.

### DESCRIPTION

Embodiments of the invention will be described below with reference to the accompanying drawings.

According to one embodiment of the invention, A semiconductor device includes a base body, an insulating layer, first contacts and a first wiring. The insulating layer is formed above the base body. The first contacts are disposed in the insulating layer. The first contacts are in contact with the base body. The first wiring is disposed around the first contacts. The first wiring has a lower height than the first contacts. The first wiring includes convex portions in a part of a bottom portion thereof.

In the following description, a side closer to a semiconductor substrate may be referred to as a lower side.

### First Embodiment

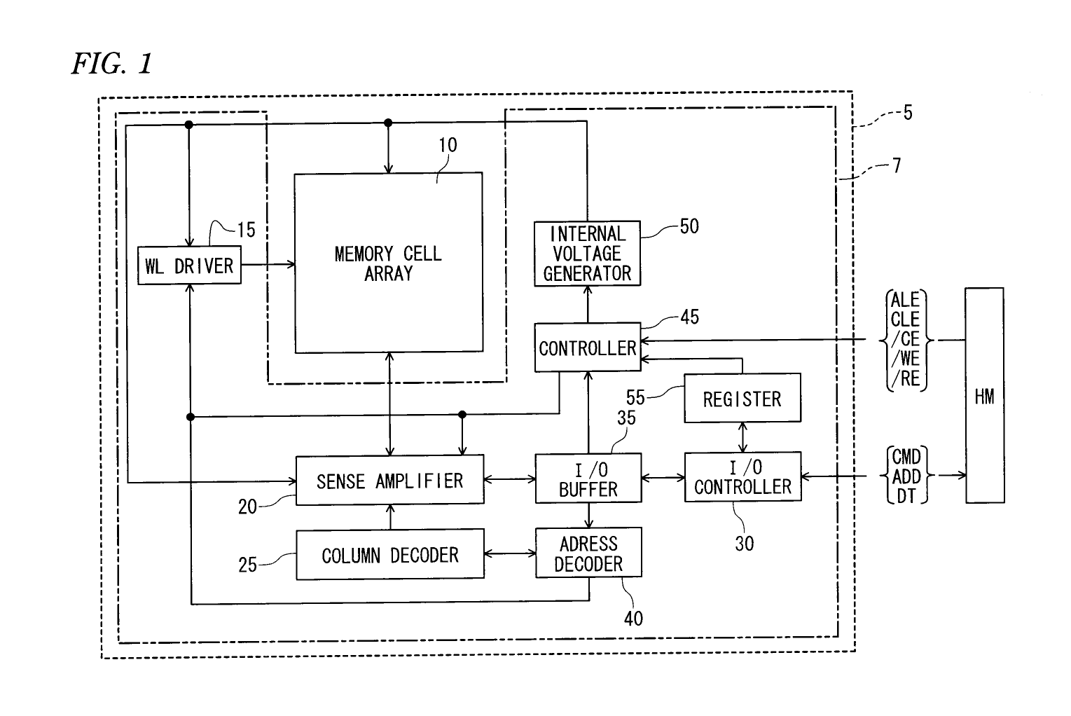

A NAND type flash memory will be described by way of example as a first embodiment. FIG. 1 is a block diagram showing the configuration of a semiconductor device 5 according to the first embodiment.

The semiconductor device 5 includes a memory cell array 10 and a peripheral circuit 7 other than the memory cell array 10. The memory cell array 10 stores data mainly. Also, the memory cell array 10 performs various actions such as reading data and writing data in accordance with an input from the peripheral circuit 7. In response to an input from the outside, the peripheral circuit 7 provides a necessary voltage to the memory cell array 10 and performs various operations to allow the semiconductor device 5 to function.

In the memory cell array 10, a plurality of memory cells are disposed in a matrix manner. Electrically rewritable EEPROM cells are used as the memory cells. The memory cell array 10 is provided with a plurality of bit lines, a plurality of word lines and a source line in order to control the voltages of the memory cells.

The peripheral circuit 7 includes a word line driver 15, a sense amplifier 20, a column decoder 25, an input/output controller 30, an input/output buffer 35, an address decoder 40, a controller 45, an internal voltage generator 50, and a register 55 as shown in FIG. 1 by way of example.

The word line driver 15 connects to the plurality of word lines. The word line driver 15 selects and drives a word line based on an output signal of the address decoder 40, to read data therefrom, write data therein, erase data therefrom, and so on.

The sense amplifier 20 detects data of a bit line when the data are read out. Also, the sense amplifier 20 applies, to a bit line, a voltage corresponding to write data when the data are written therein.

The column decoder 25 generates, based on an output signal of the address decoder 40, a column selection signal for selecting a bit line and sends the column selection signal to the sense amplifier 20.

The input/output controller 30 receives various commands CMD, address signals ADD and data DT (including write data) supplied from the outside.

Specifically, when data are written, write data are sent to the sense amplifier 20 through the input/output controller 30 and the input/output buffer 35. Also, when data are read out, read data read out by the sense amplifier 20 are sent to the input/output controller 30 through the input/output buffer 35. Then, the read data are output to an external HM (for example, a memory controller or a host) from the input/output controller 30.

An address signal ADD sent from the input/output controller 30 to the input/output buffer 35 is sent to the address decoder 40. The address decoder 40 decodes the address signal ADD, and sends a row address to the word line driver 15 and a column address to the column decoder 25.

A command CMD sent from the input/output controller 30 to the input/output buffer 35 is sent to the controller 45.

To the controller 45, external control signals such as a chip enable signal/CE, a write enable signal/WE, a read enable signal/RE, an address latch enable signal ALE, a command line enable signal CLE, etc. are supplied from the external HM.

The controller 45 generates a control signal for controlling a sequence of writing and erasing data and a control signal for controlling reading out data, based on an external control signal supplied in accordance with an operating mode and the command CMD. The control signal is sent to the word line driver 15, the sense amplifier 20, the internal voltage generator 50, etc. Using the control signal, the controller 45 totally controls various operations of the semiconductor device 5.

The controller 45 does not have to be disposed within the semiconductor device 5. That is, the controller 45 may be disposed in a semiconductor device other than the semiconductor device 5 or may be disposed in the external HM.

The internal voltage generator 50 generates voltages required for various operations of the memory cell array 10, the word line driver 15 and the sense amplifier 20, such as a readout voltage, a write-in voltage, a verify voltage, an erasing voltage, etc., in accordance with various control signals sent from the controller 45.

The register 55 is connected to the input/output controller 30 and the controller 45. The register 55 stores parameters suitable to the quality of the semiconductor device which is decided in a test process.

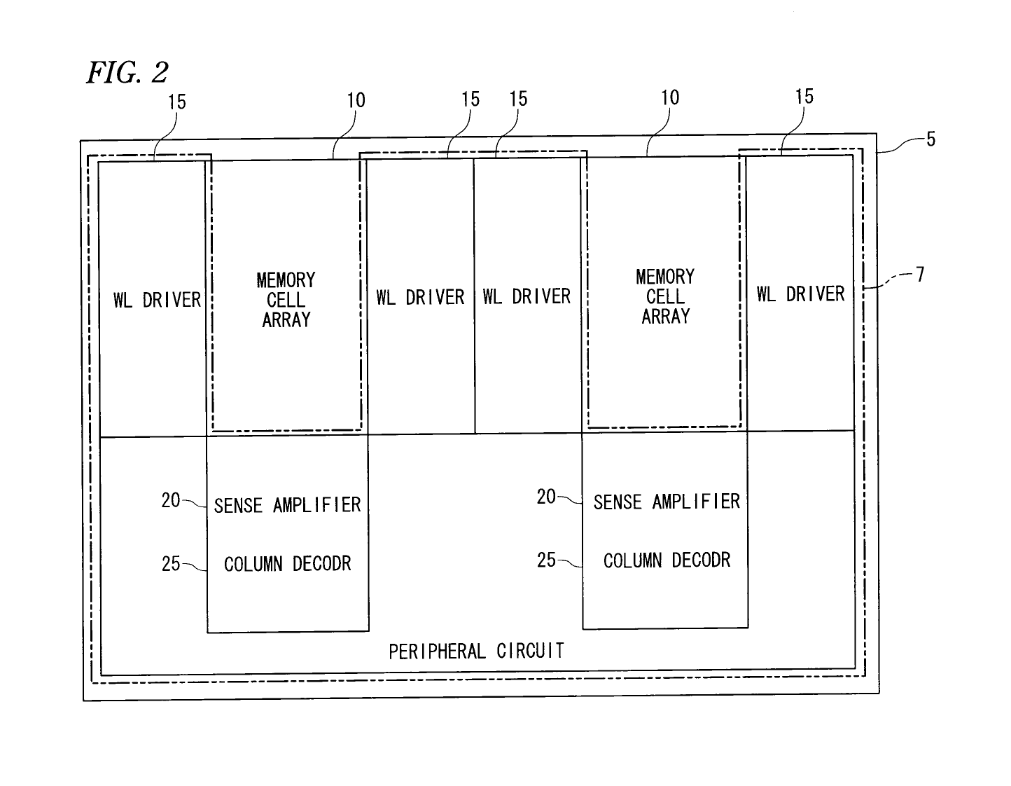

FIG. 2 shows a schematic plan view of the semiconductor device 5 according to the first embodiment shown in FIG. 1.

Two memory cell arrays 10 are provided inside the semiconductor device 5. The peripheral circuit 7 is formed in an area other than the memory cell arrays 10.

As the peripheral circuit 7, the plurality of word line drivers 15 are provided on opposite sides of each of the memory cell arrays 10. Also, the sense amplifier 20 and the column decoder 25 are provided so as to be in contact with each of the memory cell arrays 10.

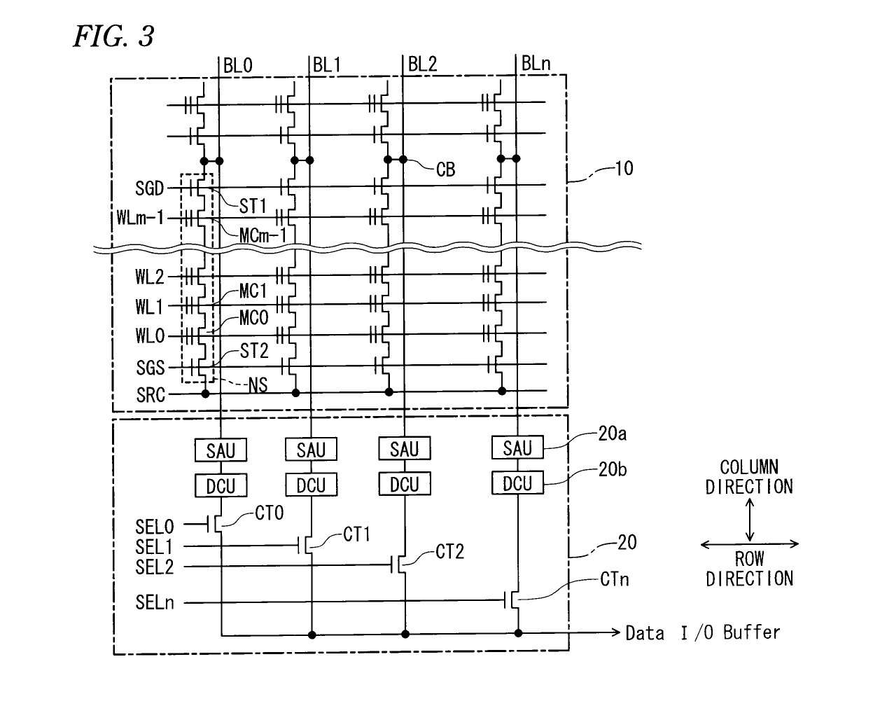

FIG. 3 is a circuit diagram schematically showing the configuration of the memory cell array 10 and the sense amplifier 20 shown in FIG. 1. The memory cell array 10 includes a plurality of NAND strings NS. Each NAND string NS includes, for example, m memory cells MC0 to MCm-1 (which are also referred to as memory cell transistors) connected in series, and selective gate transistors ST1 and ST2 connected to the opposite ends thereof respectively.

Each memory cell MC includes a charge storage layer and a control gate electrode. The charge storage layer (which may be, for example, a floating gate electrode or a trap insulating film, or which may be a film in which the floating gate electrode and the trap insulating film are stacked) is formed on a semiconductor substrate (well) via a gate insulating film therebetween. The control gate electrode is formed on the charge storage layer via an insulating film therebetween. The memory cells MC can store data in accordance with a change of a threshold voltage depending on the amount of electrons injected into the charge storage layer. For example, 1.5 bits (more than a ternary) of data can be stored in each memory cell MC.

Electric current paths of memory cells adjacent to each other in a NAND string NS are connected in series. One end of memory cells MC connected in series is connected to a source of the selective gate transistor ST1, and the other end is connected to a drain of the selective gate transistor ST2. A drain of the selective gate transistor ST1 is connected to a bit line BL through a bit line contact CB. A source of the selective gate transistor ST2 is connected to a source line SRC.

The sense amplifier 20 includes a plurality of sense amplifier units (SAU) 20a and a plurality of data control units (DCU) 20b. The sense amplifier units 20a connect to bit lines BL0 to BLn, respectively. The data control units 20b connect to the corresponding sense amplifier units 20a, respectively.

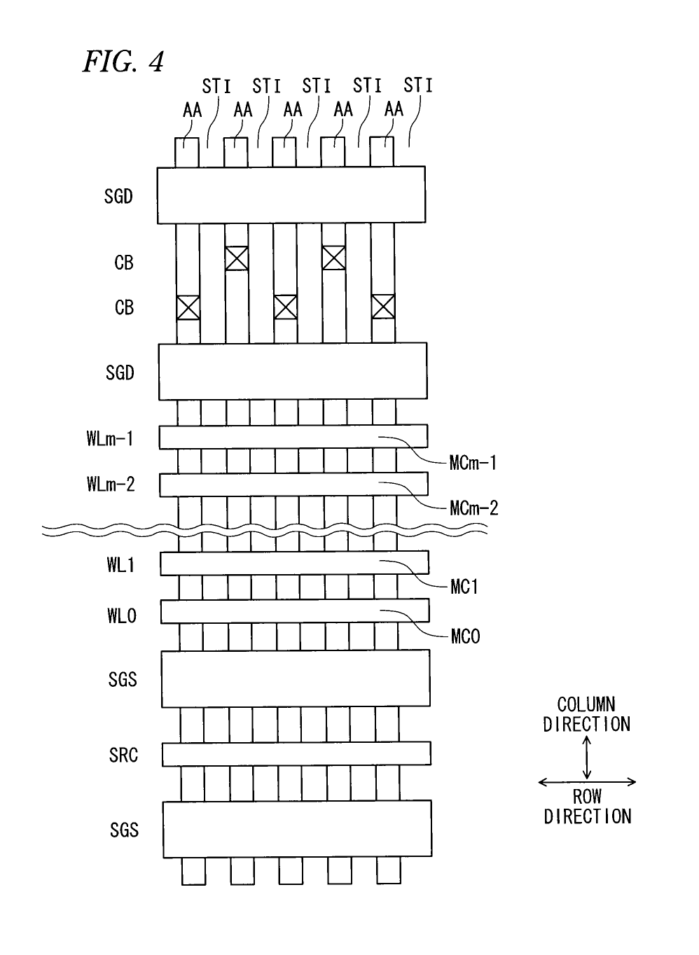

FIG. 4 shows a part of the layout of the memory cell array 10. Element isolation structures STI and active areas AA are formed in the semiconductor substrate to extend in the column direction. A plurality of word lines WL connecting gate electrodes of the memory cell transistors MC0 to MCm-1 are formed so as to extend in the row direction and cross the active areas AA. Also, selective gate lines SGS and SGD connected to gate electrodes of the selective gate transistors ST1 and ST2 are formed to extend in the row direction and disposed at positions adjacent to the word lines WL.

Bit line contacts CB are, also, formed in the active areas AA between a pair of selective gate lines SGD. The bit line contacts CB electrically connect the active areas AA and the bit lines located in a layer above the active areas AA. Since the memory cell transistors MC are formed on the active areas AA, the density of the active areas AA directly leads to the memory capacity. It is therefore desired to form the active areas AA and the element isolation structures STI at intervals based on a minimum feature size which is achieved by a lithography technique and an etching technique.

The bit line contacts CB formed on the active areas AA are also formed at intervals based on the minimum feature size in the same manner. Specifically, in FIG. 4, a distance between the centers of the bit line contacts CB is set to be about 1.41 times as long as a pitch at which the active areas are formed.

On the other hand, there are some contacts in the peripheral circuit which are formed at the same time as the bit line contacts CB are formed.

The contacts formed in the peripheral circuit are disposed based on electric circuits constituting the peripheral circuit. The electric circuits include various kinds of circuits in accordance with their functions. To this end, the contacts in the peripheral circuit are not always disposed at intervals based on the minimum feature size.

That is, of the contacts belonging to the peripheral circuit, some contacts are arranged with lower density than the bit line contacts CB.

Contacts whose arrangement density is comparatively high will be referred to as “dense contacts CH” or simply as “contacts CH.” On the other hand, contacts whose arrangement density is comparatively low will be referred to as “sparse contacts CL” or simply as “contacts CL.”

Contact holes which have not yet been filled with films or the like in the contacts CH will be referred to as “dense contact holes SH” or simply as “contact holes SH.” On the other hand, contact holes which have not yet been filled with films or the like in the contacts CL will be referred to as “sparse contact holes SL” or simply as “contact holes SL.”

Furthermore, high arrangement density of contacts will be referred to as “dense,” and low arrangement density of contacts will be referred to as “sparse.”

Specific examples of the contacts CH include the bit line contacts CB. Specific examples of the contacts CL include contacts formed in the peripheral circuit such as the sense amplifier, the column decoder, etc.

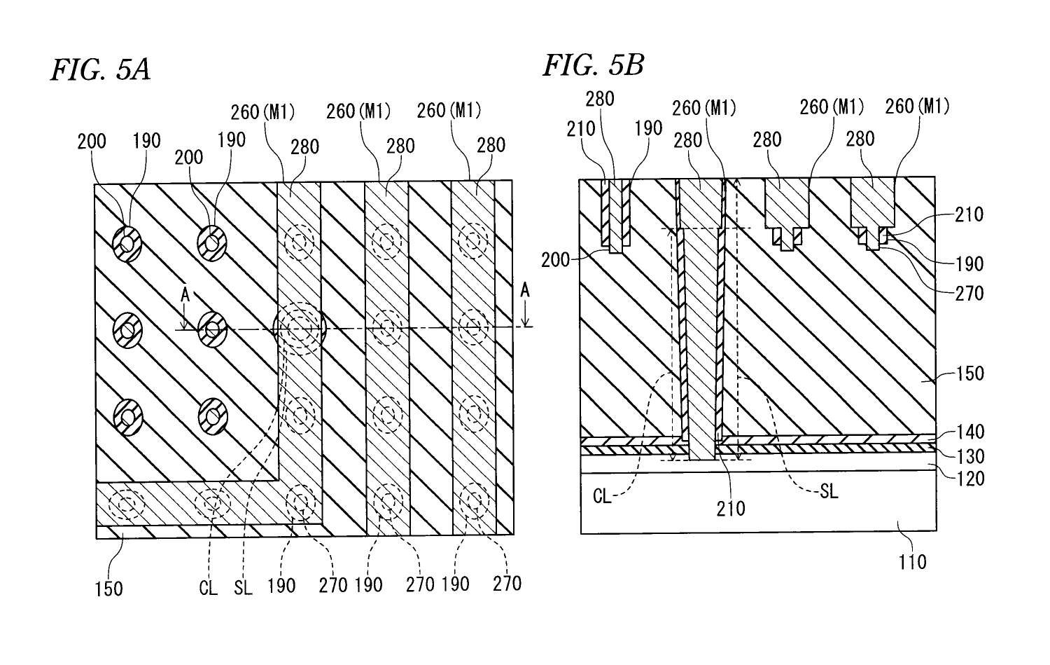

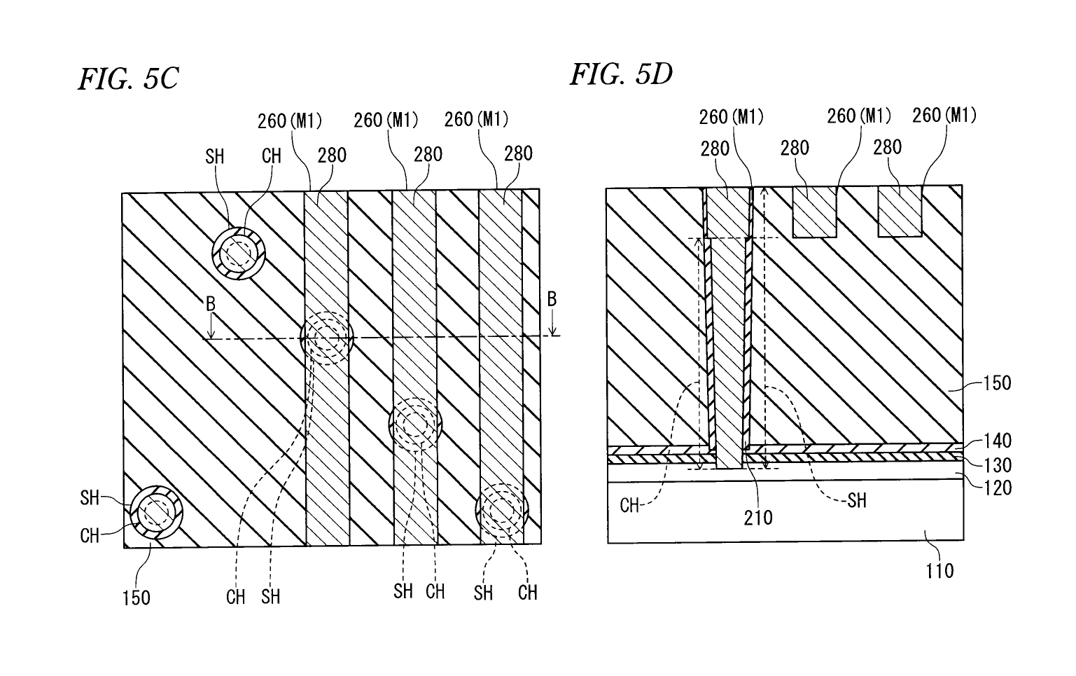

The configuration around the contact CL according to the first embodiment will be described below with reference to FIGS. 5A and 5B.

FIG. 5A is a plan view around a contact CL which is formed sparsely in the peripheral circuit. The structure under a conductive material 280 is also depicted by dotted lines. FIG. 5B is a sectional view taken along a line A-A in FIG. 5A.

As shown in FIG. 5A and FIG. 5B, the contact CL and a contact hole SL are disposed substantially at the center of each drawing.

The contact hole SL is provided to penetrate through a first interlayer insulating layer 150 and to reach an impurity diffusion layer 120. A spacer film 210 is formed inside the contact hole SL. The contact CL and a first wiring M1 are formed inside the spacer film 210. For example, a silicon oxide film or a silicon nitride film is used as the spacer film 210.

The contact CL is formed inside the contact hole SL. Of the inside of the contact hole SL, an upper portion of the contact CL constitutes a part of the first wiring M1. A conductive material 280 is formed inside the first wiring M1 and the contact CL. The first wiring M1 electrically connects the impurity diffusion layer 120 through the contact CL.

Also, as shown in FIG. 5A, first wirings M1 and dummy holes (second holes) 190 are disposed around the contact CL. The first wirings M1 and the dummy holes 190 are disposed in the following manner. Wiring pitches of the first wirings M1 in an X direction (in the right and left directions on the sheet of FIG. 5A) are substantially equal to those of the dummy holes 190 in the X direction. Wiring pitches of the first wirings M1 in a Y direction (in the upper and lower directions on the sheet of FIG. 5A) are substantially equal to those of the dummy holes 190 in the Y direction. The wiring pitches of the dummy holes 190 in the X direction may be substantially equal to those of the dummy holes 190 in the Y direction. Here, the “pitch” means a length of a cycle of a repeated pattern. The X and Y directions are perpendicular to each other. The X and Y directions may be defined on a surface of the semiconductor layer 110.

In each first wiring M1, a conductive material 280 is formed inside a first wiring trench 260. A contact CL or an anchor recess portion 270 is provided in a bottom portion of the first wiring trench 260 as will be described later. For example, titanium, tantalum, titanium nitride, tantalum nitride, tungsten, silicon, copper or a laminate of these is used as the conductive material 280.

The contact CL and the anchor recess portions 270 in an area (which is an example of a first area) where the contact CL is formed are arranged in the X and Y directions in a matrix manner as shown in FIGS. 5A and 5B. Where there are provided a plurality of the contacts CL, pitches of centers of the contacts CL in the X direction and pitches of centers of the anchor recess portions 270 in the X directions may be substantially equal to each other.

Each dummy hole 190 is formed with a depth down to a middle of the first interlayer insulating layer 150. Some dummy holes 190 are provided in areas where the first wirings M1 are formed, and the other dummy holes 190 are provided independently. Here, “to be provided independently” means to be provided in an area where the first wiring M1 is not formed.

The dummy holes 190 are provided in the areas where the first wirings M1 are formed. The dummy holes 190 are formed in bottom portions of the first wiring trenches 260. A spacer film 210 is formed inside each dummy hole 190. The anchor recess portion (first recess portion) 270 is disposed inside the spacer film 210.

The anchor recess portion 270 is provided inside the dummy hole 190 and in a bottom portion of the first wiring trench 260. The anchor recess portion 270 is a recess portion that is provided in the first interlayer insulating layer 150. The anchor recess portion 270 has such a depth that the anchor recess portion 270 does not reach the impurity diffusion layer 120. A conductive material 280 is formed inside the anchor recess portion 270. To say in other words, the first wiring trench 260 includes the anchor recess portion 270 in its lower portion, and the conductive material 280 is formed in the first wiring trench 260 including the anchor recess portion 270. To say in further other words, the first wiring M1 includes a convex-shaped portion (convex portion) where the conductive material 280 is filled in the anchor recess portion 270.

A dummy recess portion (second recess portion) 200 is disposed on a lower side of each dummy hole 190 which is provided independently.

The spacer film 210 is formed inside the dummy hole 190. The dummy recess portion 200 is formed inside the spacer film 210 and in a bottom portion thereof. The conductive material 280 is formed inside the spacer film 210 and in the dummy recess portion 200.

The configuration around the contacts CH according to the first embodiment will be described below with reference to FIGS. 5C and 5D.

FIG. 5C is a plan view around the contact holes SH and the contacts CH which are densely formed. It is noted that FIG. 5C shows the structure below the conductive material 280 by dotted lines. FIG. 5D is a sectional view taken along a line B-B in FIG. 5C.

As shown in FIG. 5C, the contacts CH are arranged more densely than the contact CL is arranged as shown in FIG. 5A.

The wiring trenches 260 around the contacts CH are not formed with anchor recess portions 270 in lower portions thereof (see FIGS. 5C and 5D).

As shown in FIG. 5D, the contact holes SH are formed so as to penetrate through the first interlayer insulating layer 150 and to reach the impurity diffusion layer 120. The contact holes SH have similar structures to the structure of the contact hole SL.

The contacts CH have similar structures to the structure of the contact CL. The contacts CH are formed inside the respective contact holes SH. Of the inside of the contact holes SH, upper portions of the contacts CH constitute a part of the first wirings M1. The conductive material 280 is formed inside the first wirings M1 and the contacts CH. The first wirings M1 electrically connects the impurity diffusion layer 120 through the contacts CH.

It is not necessary for the first wirings M1 to be formed in the upper portions of the contact holes SH as shown in FIGS. 5C and 5D. Where the first wirings M1 are not formed in the upper portions of the contact holes SH, the contacts CH are formed in the entire contact holes SH.

Referring back to FIGS. 5A and 5B, the dummy holes 190 in an area where the contact hole SL is formed are disposed in a grid manner. The grid interval is typically a minimum distance between the contacts CH disposed densely or a constant multiple of the minimum distance. However, the grid interval may be a desired distance which is equal to or larger than the minimum distance.

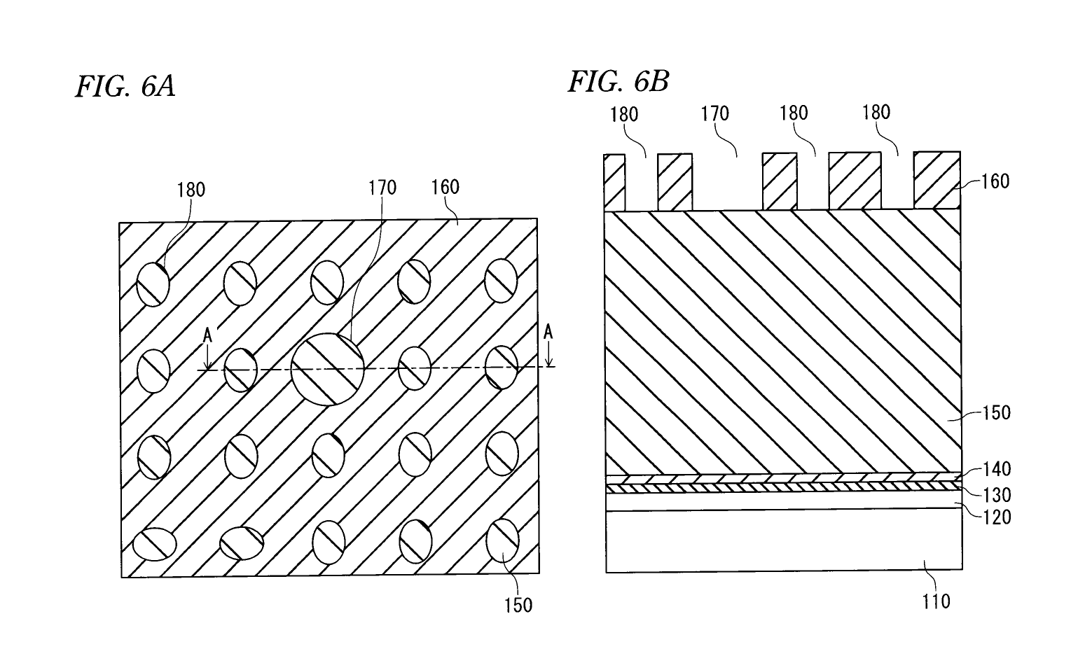

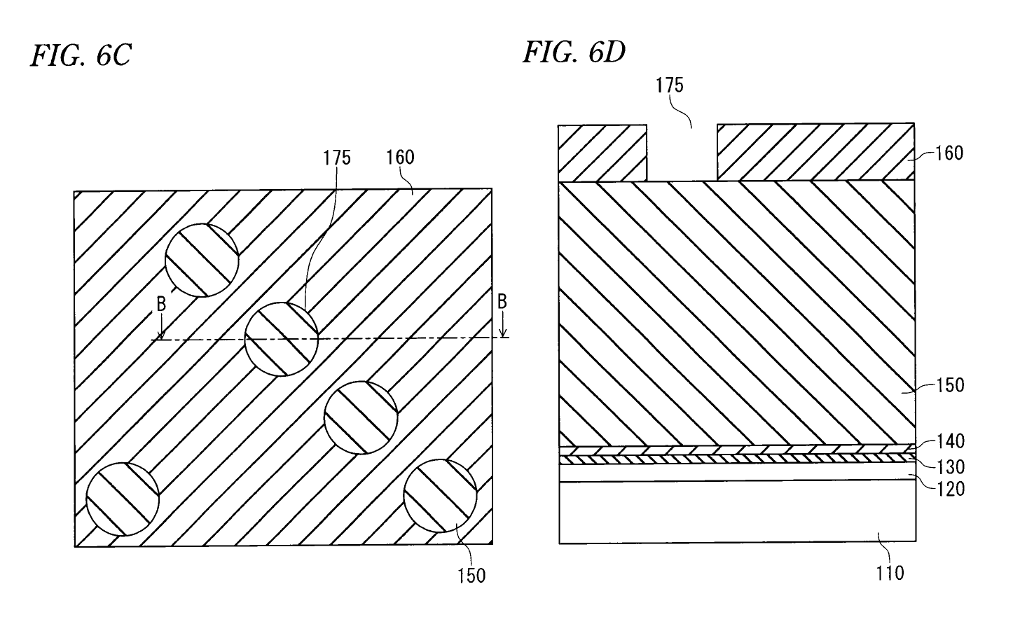

A method for manufacturing the semiconductor device 5 according to the first embodiment will be described below with reference to FIGS. 6A to 13D.

At first, as shown in FIGS. 6B and 6D, the impurity diffusion layer 120 is formed in a semiconductor layer 110 (which is an example of a base body) by ion injection or the like. Furthermore, the element isolation structures STI (not shown) and the memory cell transistors (not shown) are formed.

Next, a silicon oxide film 130, a stopper film 140, and the first interlayer insulating layer 150 are formed to cover the semiconductor substrate 110. For example, a silicon nitride film is used as the stopper film 140. For example, a silicon oxide film is used as the first interlayer insulating layer 150. CMP (Chemical Mechanical Polishing) may be performed to flatter the formed structure in accordance with necessity. Thereafter, a mask pattern 160 is formed using a lithography method.

Mask holes 175 which will be used to process dense contact holes SH (may be simply referred to as “mask holes 175”), mask holes 170 which will be used to process sparse contact holes SL (may be simply referred to as “mask holes 170”) and dummy mask holes 180 which will be used to form dummy holes (which may be simply referred to as “dummy mask holes 180”) are formed in the mask pattern 160.

Specifically, as shown in FIG. 6A, the dummy mask holes 180 are formed around the mask holes 170. The dummy mask holes 180 are disposed so that a longitudinal direction of each dummy mask hole 180 is parallel to an extending direction of each first wiring trench 260 which will be described later. The dummy mask hole 180 may be disposed not in parallel to the first wiring trench 260 but in a desired direction. As shown in FIG. 6C, no dummy mask holes 180 are formed around the mask holes 175. The mask holes 175 are disposed more densely than the mask holes 170 are disposed.

In a typical example of the embodiment, each of the mask holes 170, 175 has a circular shape of about 80 to 100 nm, and each of the dummy mask holes 180 has about 40 to 60 nm in its longitudinal direction and about 20 to 30 nm in its minor axis.

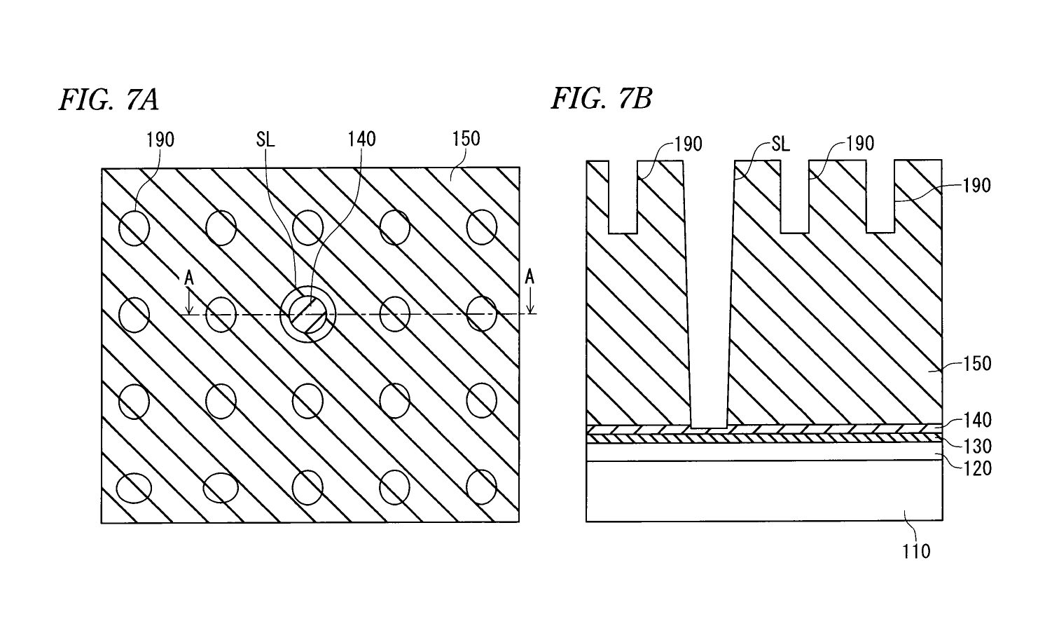

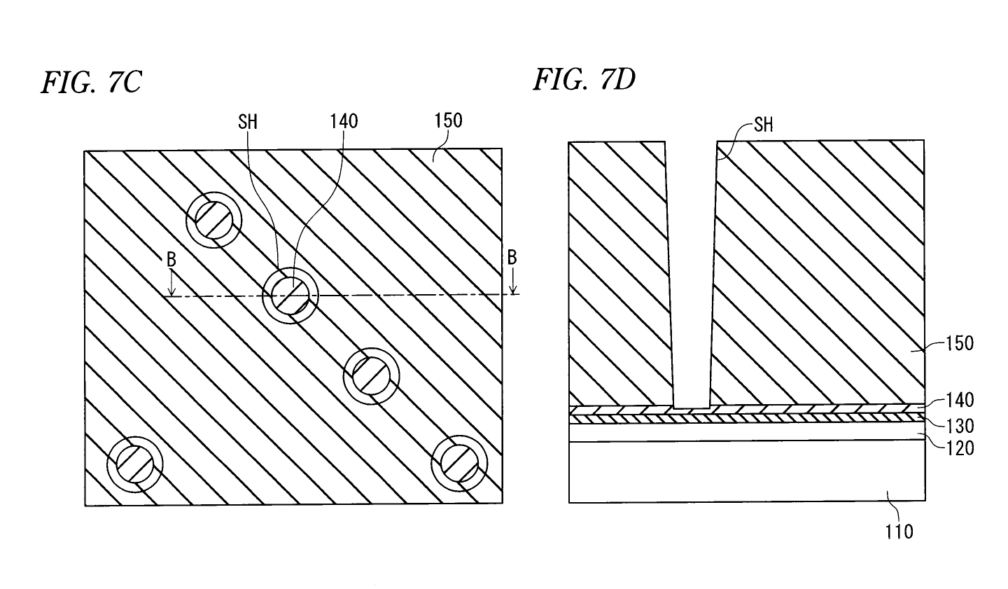

Next, as shown in FIGS. 7A to 7D, the first interlayer insulating layer 150 is processed by RIE using the mask pattern 160 as a mask. Thereafter, the mask pattern 160 is removed.

As a result, the dense contact holes SH, the sparse contact holes SL and the dummy holes 190 are formed. The dense contact holes SH and the sparse contact holes SL penetrate through the first interlayer insulating layer 150 and reach a middle of the stopper film 140.

Conditions with which a certain selection ratio between the first interlayer insulating layer 150 and the stopper film 140 can be secured are selected. Thereby, the etching can be stopped in the stopper film 140.

Also, the etching is stopped in a middle of the first interlayer insulating layer 150 so that the dummy holes 190 cannot reach the impurity diffusion layer 120, the memory cell transistors (not shown), etc. This is because the dummy mask holes 180 are smaller than the mask holes 170, 175 and the etching rate of the dummy holes 190 is lower.

For example, the etching rate of the dummy holes 190 becomes low for the following reason. An etchant in etching gas hardly reaches the bottom of a hole whose aspect ratio (ratio of depth to width) is high. Thus, the etching rate becomes low. This phenomenon may be referred to as a “micro-loading effect based on an aspect ratio.”

In an example corresponding to the above described typical example, the diameter of each dense contact hole SH is 40 to 60 nm in its top, and the shape of each dummy hole 190 in the upper portion thereof is about 30 to 50 nm in its longitudinal direction and about 10 to 20 nm in its minor axis.

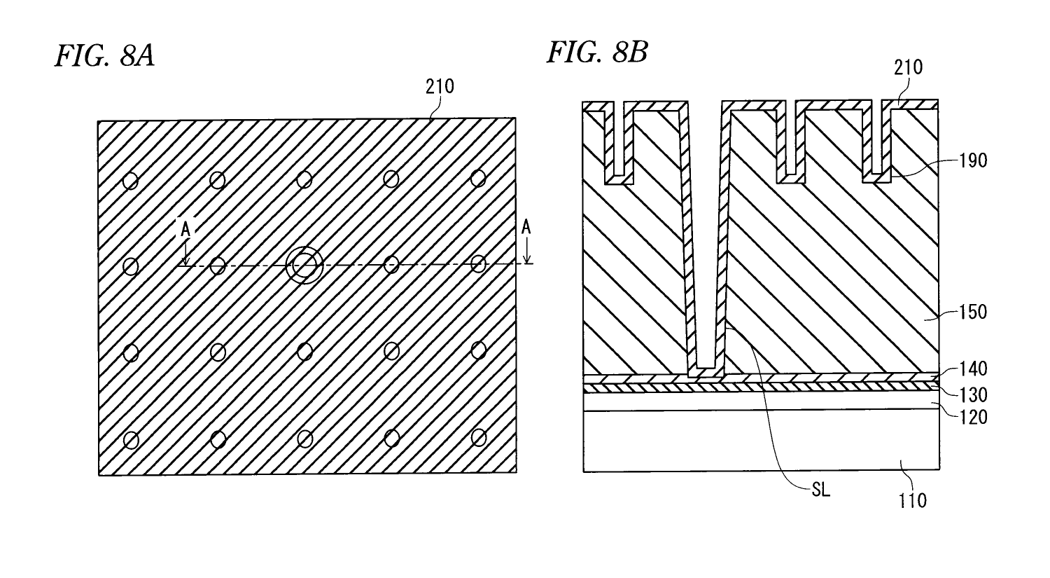

Next, as shown in FIGS. 8A to 8D, the spacer film 210 is formed. The spacer film 210 makes it possible to reduce the inner diameters of the contact holes SL, SH and to shrink the semiconductor device. For example, a silicon oxide film or a silicon nitride film is used as the spacer film 210. A film formation method superior in coverage suffices as a method for forming the spacer film 210. For example, a low-pressure CVD method, an ALD (Atomic Layer Deposition) method, or the like, may be used.

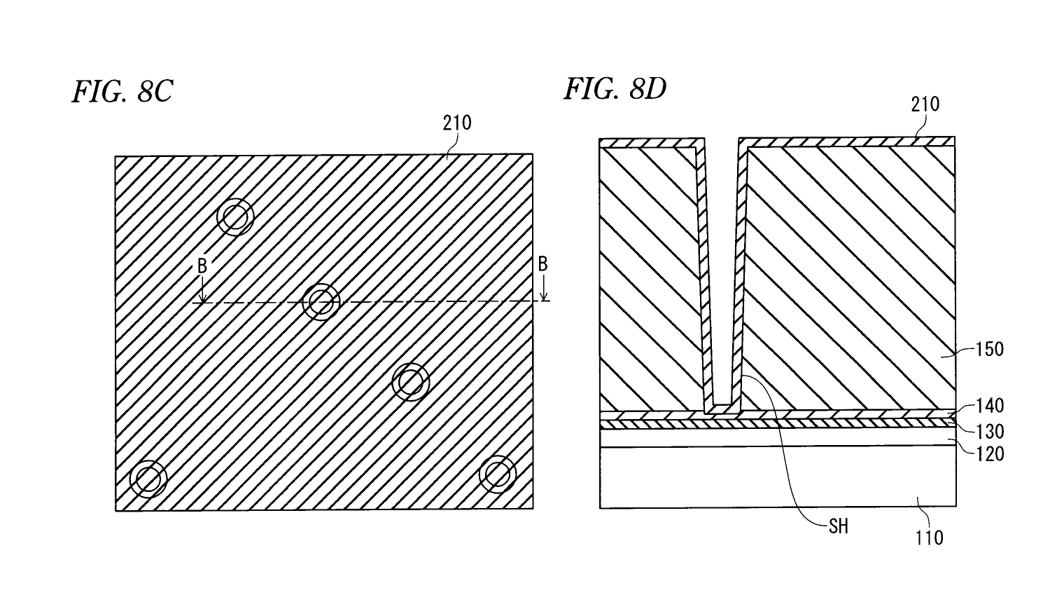

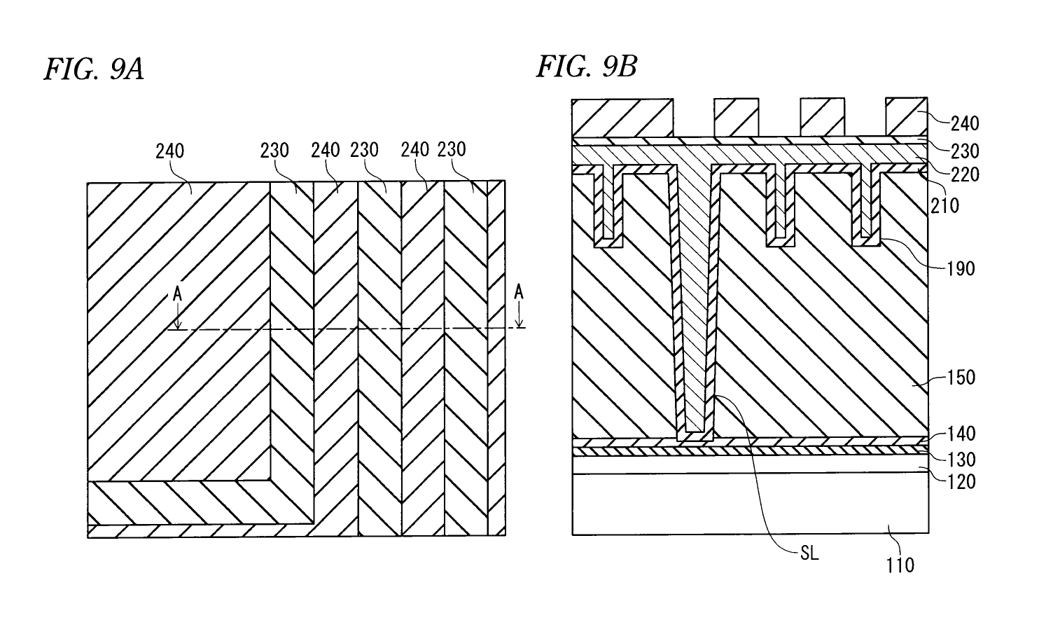

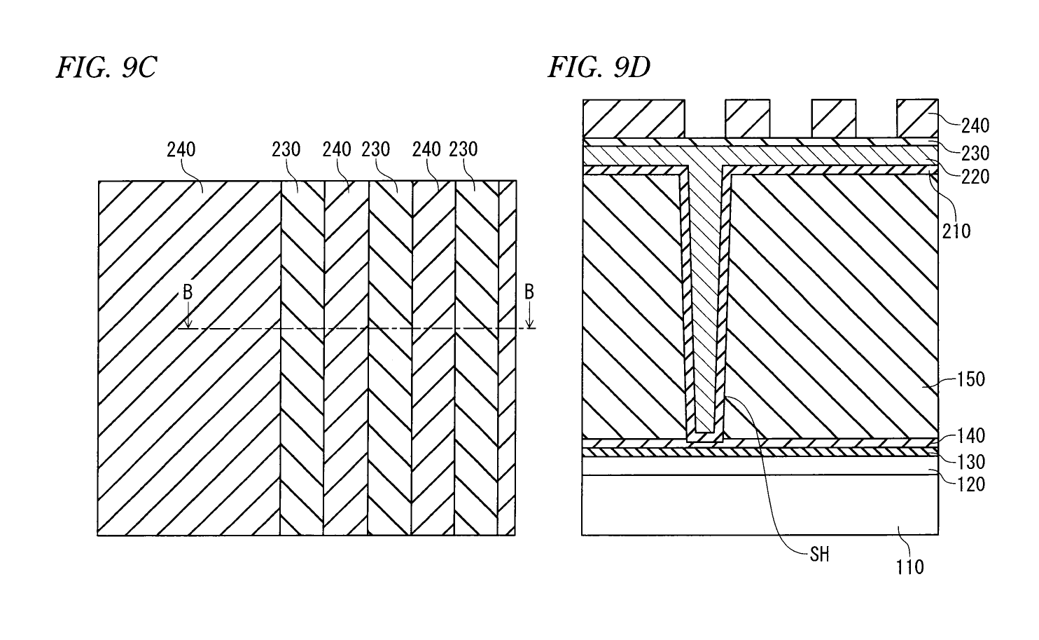

Next, as shown in FIGS. 9A to 9D, a first resist material 220 and a silicon oxide film 230 are formed, and a mask pattern 240 using a second resist material is formed.

As shown in FIGS. 9B and 9D, the contact holes SL, SH are filled with the first resist material 220, so that flattening can be achieved. As a result, the mask pattern 240 can be formed easily. For example, SOG (Spin On Glass) or the like may be used as the silicon oxide film 230.

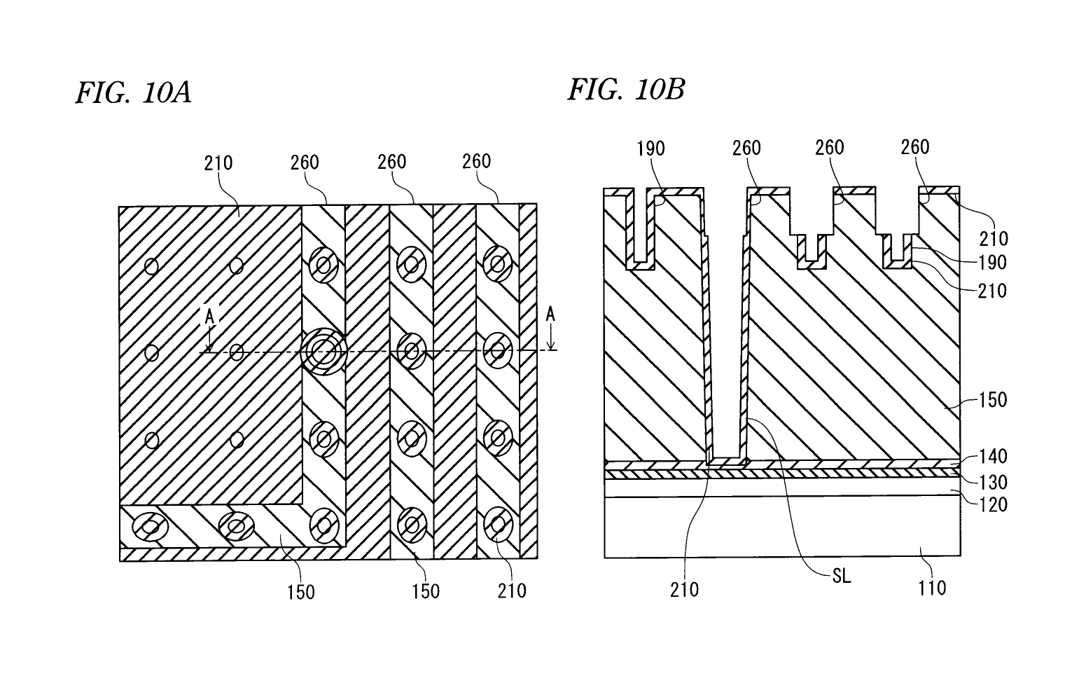

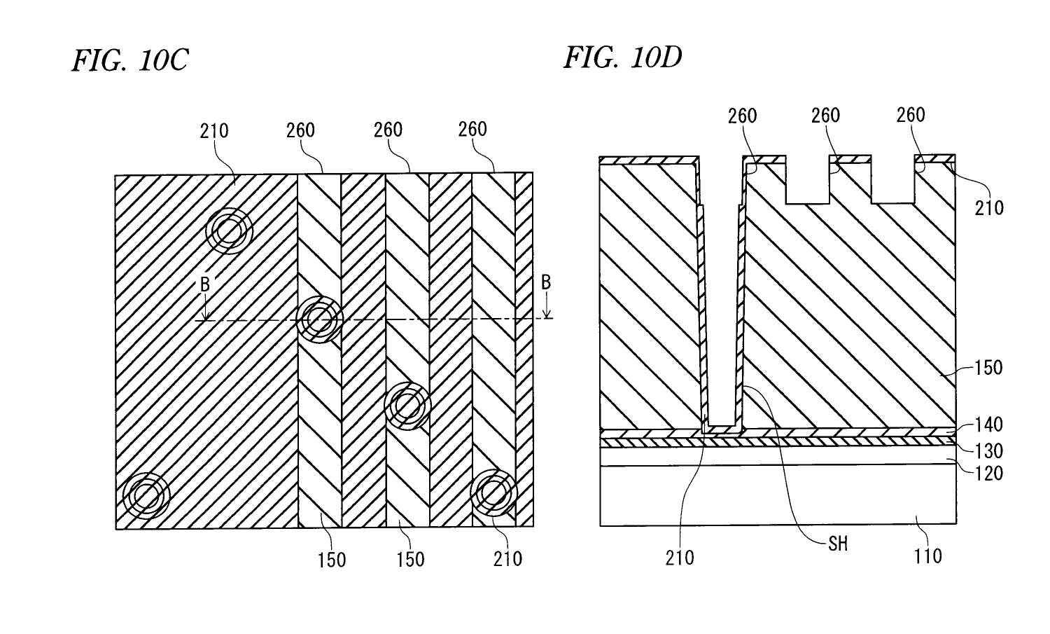

Next, as shown in FIGS. 10A to 10D, the first wiring trenches 260 are formed. The silicon oxide film 230 and the first resist material 220 are etched using the mask pattern 240 as a mask. Thereafter, the spacer film 210 and the first interlayer insulating layer 150 are etched using the silicon oxide film 230 and the first resist material 220 as mask materials. Subsequently, the first resist material 220 is removed.

Due to the etching process, the first wiring trenches 260 are formed on a part of the dummy holes 190 around the contact hole SL. To say in other words, a part of the dummy holes 190 are provided in bottom portions of the first wiring trenches 260. Also, the first wiring trenches 260 are formed in a region where the dense contacts CL (contact holes SL) are disposed (see FIGS. 10C and 10D).

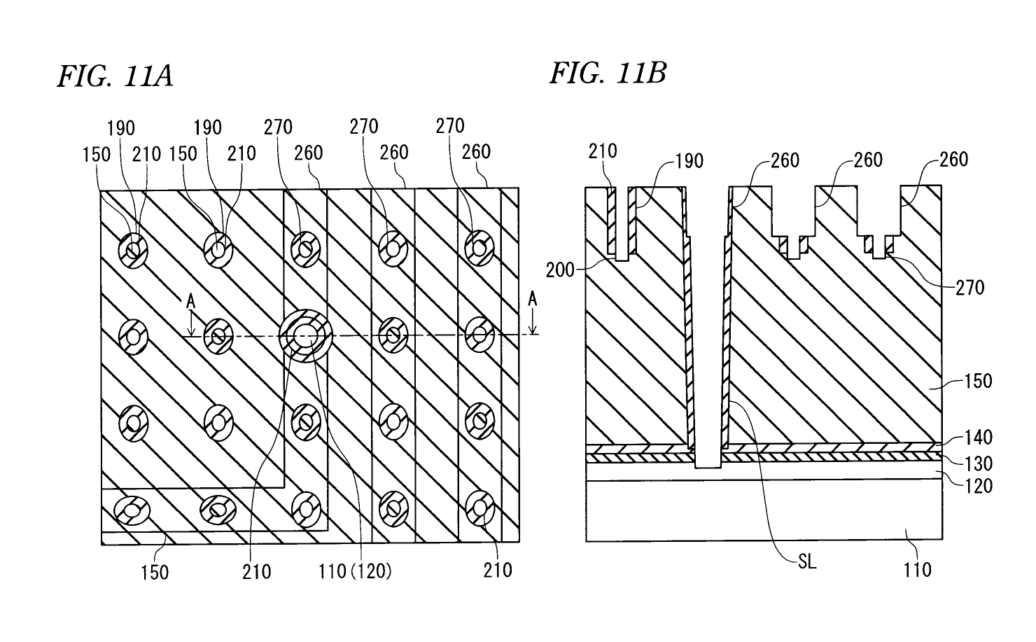

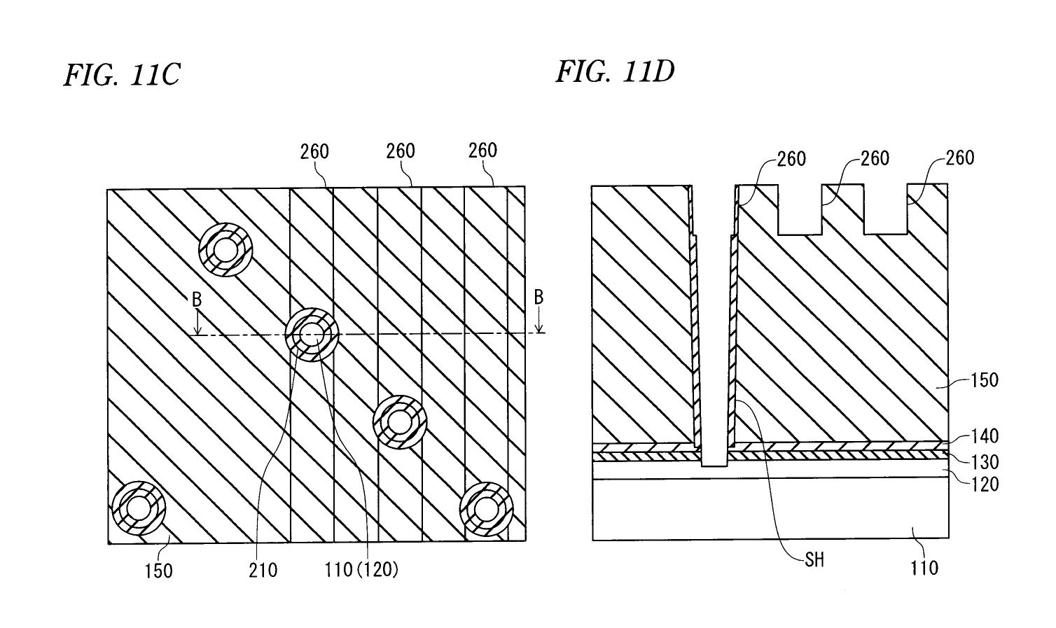

Next, as shown in FIGS. 11A to 11D, all the surface is etched back by RIE. The etching-back treatment removes the spacer film 210, the stopper film 140 and the silicon oxide film 130 from the lower portions of the contact holes SL, SH. Also, as a result of the etching-back treatment, the sparse contact holes SL and the dense contact holes SH reach the impurity diffusion layer 120. Here, it is desired to perform the etching-back treatment to prevent the sparse contact holes SL and the dense contact holes SH from penetrating through the impurity diffusion layer 120.

By the above-described treatment, the spacer film 210 and the first interlayer insulating layer 150 in the bottom surface are etched within the areas where the spacer film 210 is formed on the side walls of the dummy holes 190. Due to the etching process, the dummy recess portions 200 are formed in lower portions of the independent dummy holes 190. On the other hand, the anchor recess portion 270 is formed in the lower portion of each dummy hole 190 in the area where the first wiring trench 260 is formed. To say in other words, each first wiring trench 260 around the sparse contact hole SL (in the region where the sparse contacts CL are formed) includes the anchor recess portion 270 in its bottom portion. On the other hand, no anchor recess portions 270 are formed in the first wiring trenches 260 around the dense contact holes SH (in the region where the dense contacts CH are formed).

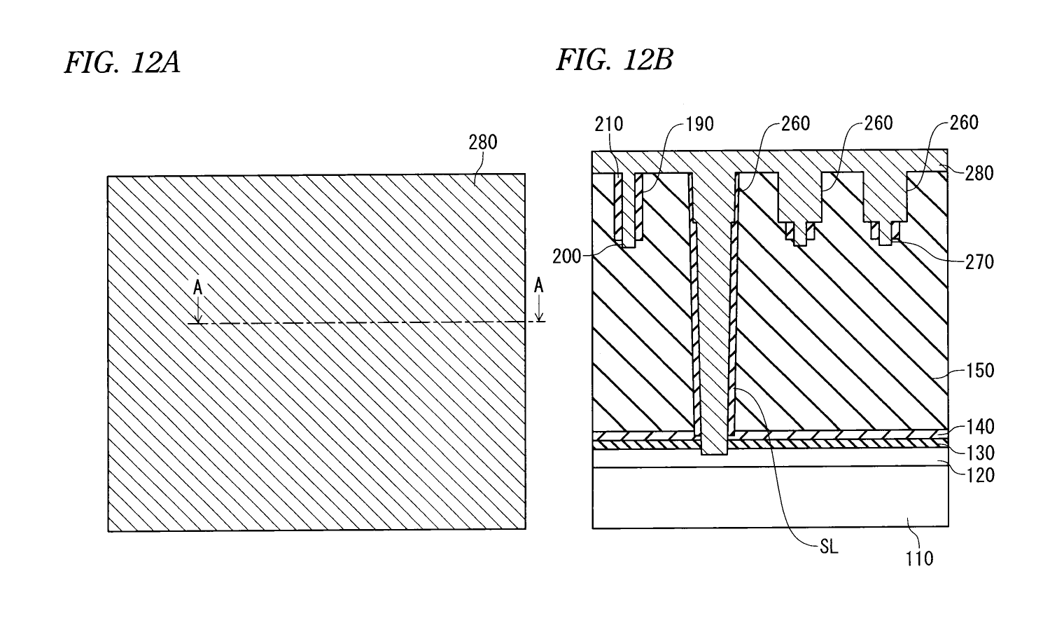

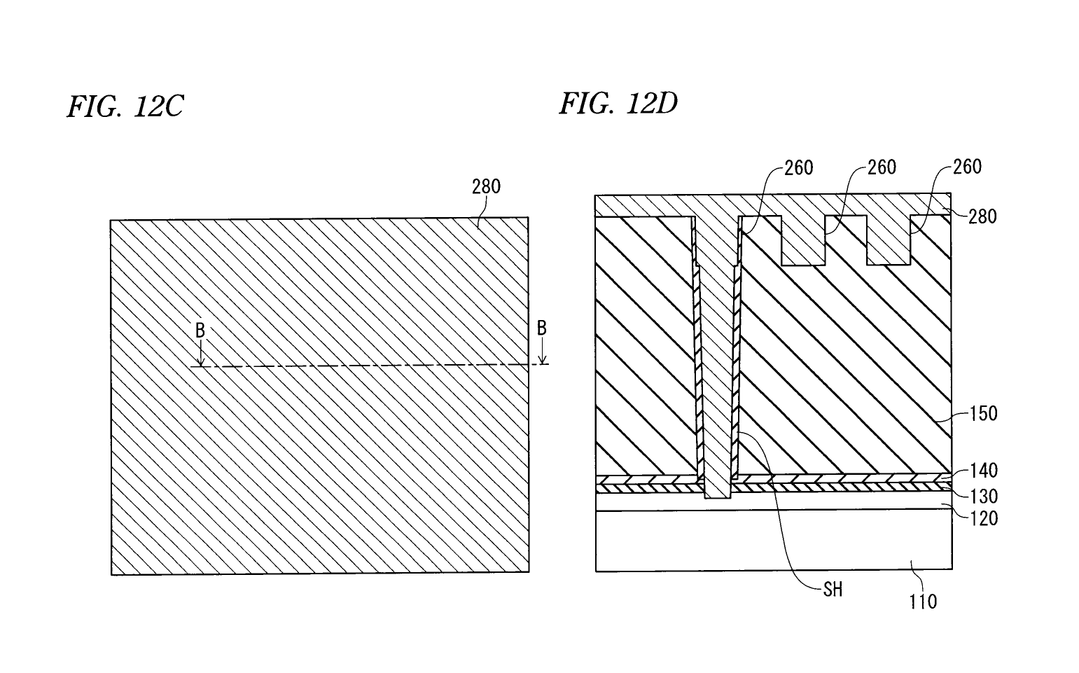

Next, as shown in FIGS. 12A to 12D, the conductive material 280 is formed. The first wiring trenches 260, the inside of the spacer film 210 of the dummy holes 190, the inside of the spacer film 210 of the contact holes SL, SH, the dummy recess portions 200, the anchor recess portions 270, etc., are filled with the conductive material 280.

For example, the conductive material 280 contains a barrier metal layer and a metal layer. For example, titanium, tantalum, titanium nitride, tantalum nitride or a lamination of these is used for the barrier metal layer. Tungsten, copper or the like is used for the metal layer. As a film formation method, a plasma CVD method, a metal plating method, a sputtering method, etc. is used in accordance with the material.

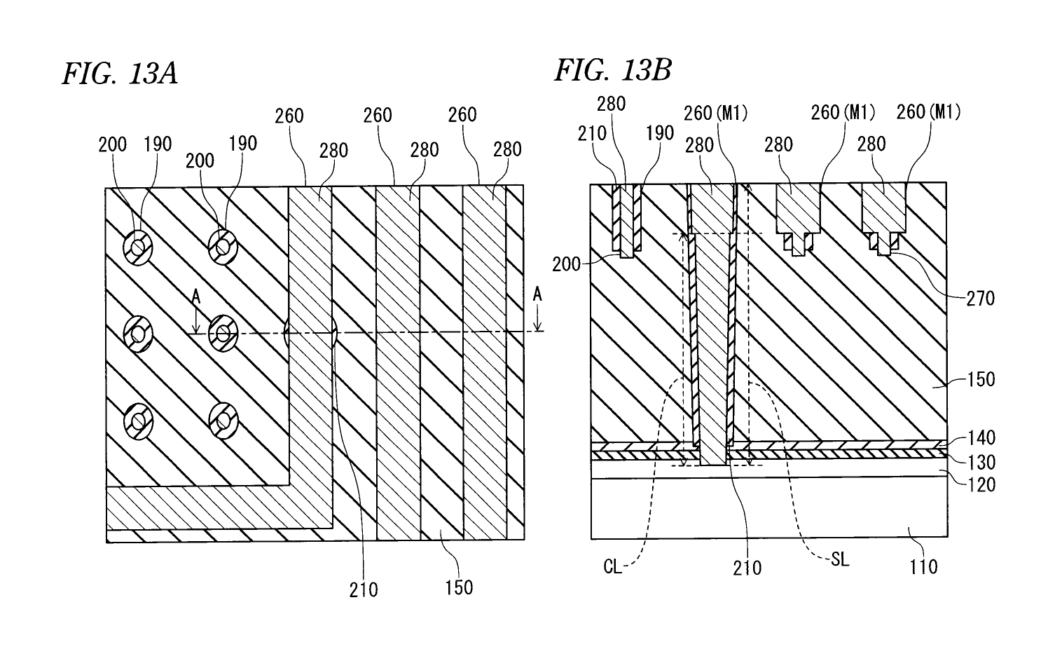

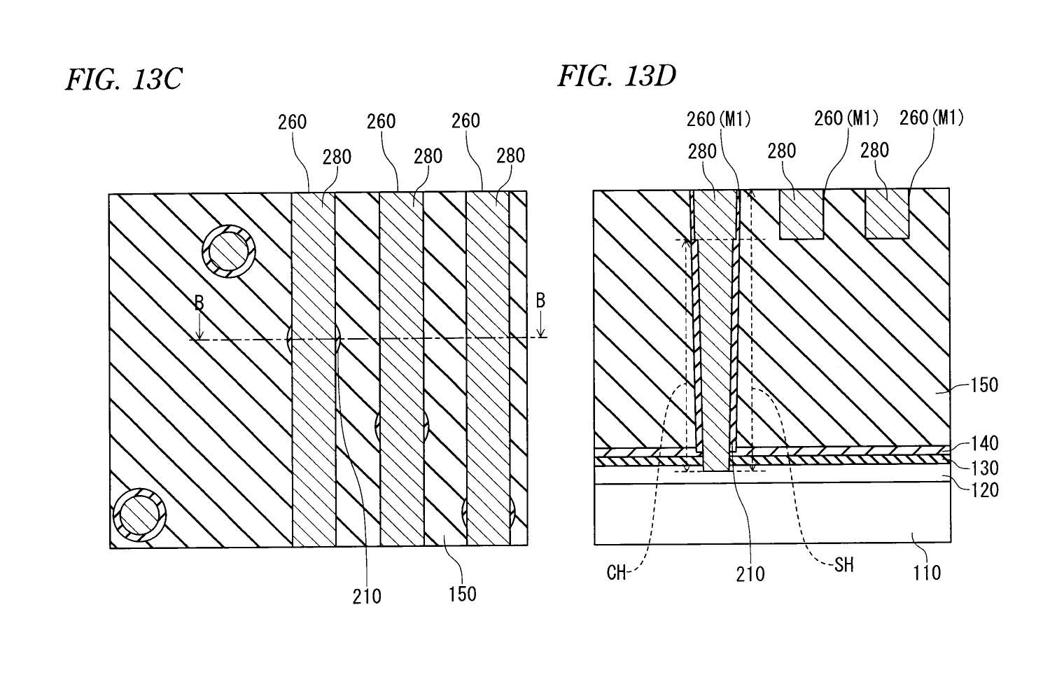

Next, as shown in FIGS. 13A to 13D, flattening is performed by CMP until the first interlayer insulating film 150 is exposed. By the CMP processing, the first wirings M1 are formed. Also, the contacts CL are formed inside the contact holes SL and in the bottom portions of the first wirings M1. The contacts CH are formed inside the contact holes SH and in the bottom portions of the first wirings M1.

Thereafter, various wiring layers and circuit elements are formed using general manufacturing methods. Thus, the semiconductor device 5 according to the first embodiment is manufactured.

When the dummy holes 190 are disposed around the sparse contact hole SL as in the aforementioned manufacturing method, some advantages can be obtained as follows.

The first advantage is that the dense contact holes SH and the sparse contact holes SL can be simultaneously processed easily by RIE. To say in other words, this advantage can reduce the “micro-loading effect based on density,” which effect will be described below.

Let consider a case where there is no dummy hole 190 around a sparse contact hole SL. Etching a region having a certain area and including the dense contact holes SH contain more objects to be etched than etching a region having the same certain area and including the sparse contact holes SL. Since the more objects is to be etched, more etchant in etching gas is consumed near the dense contact holes SH. That is, the etchant concentration becomes relatively low, and the etching rate becomes low.

That is, this means that the etching rate of the dense contact hole SH is lower than the etching rate of the sparse contact hole SL. In other words, the etching rate of the sparse contact hole SL is higher than the etching rate of the dense contact hole SH. The phenomenon that the etching rate differs due to the arrangement density in this manner will be referred to as a “micro-loading effect based on density.”

Where there is no dummy hole 190, when the etching conditions are optimized for processing the dense contact holes SH in the etching of FIGS. 7A to 7D, the sparse contact holes SL would be over-etched. If the contact holes SL are over-etched, etching is not stopped in the silicon oxide film 130 or the stopper film 140 but the contact holes SL may penetrate through the impurity diffusion layer 120. If the contact holes SL penetrate through the impurity diffusion layer 120, increase of junction leakage and/or increase of contact resistance between each contact CL and the impurity diffusion layer 120 may occur after the contact CL is formed.

The increase of the contact resistance is caused because of the following two reasons.

The first reason is that a contact area between the contact CL and the impurity diffusion layer 120 is reduced. If the contact hole SL stops in the middle of the impurity diffusion layer 120, a side surface of the contact CL and a bottom surface of the contact CL serve as contact portions between the contact CL and the impurity diffusion layer 120.

On the other hand, if the contact hole SL penetrates through the impurity diffusion layer 120, only the side surface of the contact CL serves as a contact portion between the contact CL and the impurity diffusion layer 120. Thus, the area of the contact portion(s) is reduced.

The second reason is that the spacer film 120 is formed in the contact portion between the contact CL and the impurity diffusion layer 120. If the contact hole SL penetrates through the impurity diffusion layer 120 at the time of the etching process in FIGS. 7A to 7D, the contact hole SL is in contact with the impurity diffusion layer 120 in its side surface.

In the process of forming the spacer film 210 shown in FIGS. 8A to 8D, the spacer film 210 is formed in the contact portion between the contact hole SL and the impurity diffusion layer 120. The spacer film 210 is not removed in the following RIE process etc. but remains. As a result, even after the conductive material 280 is formed inside the contact SL and the contact CL is formed, the spacer film 210 remains in the contact portion between the contact CL and the impurity diffusion layer 120. Thus, the contact resistance between the contact CL and the impurity diffusion layer 120 becomes high.

Of course, when the etching conditions of the RIE are optimized for the sparse contact holes SL in order to avoid the sparse contact holes SL penetrate through the impurity diffusion layer 120, the dense contact holes SH are under-etched at this time. That is, the dense contacts CH cannot be electrically connected to the impurity diffusion layer 120 but so-called open failure occurs.

Therefore, the dummy holes 190 are disposed around the sparse contact holes SL as in the first embodiment, so that the phenomenon can be reduced.

Specifically, when the dummy holes 190 are disposed, objects to be etched increase around the sparse contact holes SL. Due to the increase of objects to be etched, a difference in etchant concentration between the dense contact holes SH and the sparse contact holes SL is reduced. That is, the difference in etching rate is reduced. Due to the reduction of the difference in etching rate, both the contact holes SL and the contact holes SH can be stopped in the stopper film 140 when the contact holes SL and the contact holes SH are etched as shown in FIGS. 7A to 7D.

The second advantage is that the mask holes 170 can be formed easily by the lithography method. That is, when the dummy mask holes 180 are formed around the mask holes 170, it becomes easy to form the mask holes 170.

Forming a mask pattern using a lithography method involves imaging by an optical system. In the imaging, to form a periodical pattern is easier than to form an isolated pattern. That is, when the dummy mask holes 180 are formed around the mask holes 170, the mask holes 170 can be formed easily.

Also, if the arrangement distance between each dummy mask hole 180 and the mask hole 170 is set to be constant times as long as the minimum interval at which the contacts CH are disposed densely, the above described advantage of the lithography can be utilized.

If the lithography method already has a sufficient depth of focus (focus range where a certain imaging performance can be kept) and only other advantages which will be described later need to be enjoyed, it is not necessary to provide the dummy mask holes 180 as described above.

Furthermore, the third advantage is that an adhesion property of the first wirings M1 can be improved. That is, as shown in FIGS. 5A and 5B, the anchor recess portions 270 are disposed in the bottom portions of the first wirings M1. Due to the existence of the anchor recess portions 270, a contact area between the first wirings M1 and the first interlayer insulating layer 150 increases. The increase of the contact area causes the first wiring M1 to adhere to the first interlayer insulating layer 150 more firmly and to hardly separate from the first interlayer insulating layer 150.

In order to improve the adhesion property, it is more desirable that a direction in which the major axis of the first wirings M1 extends coincides with longitudinal directions of the anchor recess portions 270.

The first embodiment, as has been described above, can facilitate to form a resist pattern using a lithography method, prevent a contact hole from penetrating when the contact hole is formed using RIE, and improve a adhesion property of a wiring layer to an interlayer insulating layer.

According to a modification example of the first embodiment, the spacer film 210 may not be provided.

Also, to another modification example of the first embodiment, the stopper film 140 may not be provided. In this case, in the etching process of FIGS. 7A and 7B, the contact holes SL and SH are processed to reach the silicon oxide film 130 or the impurity diffusion layer 120. In this case, in the etching process of FIGS. 11A and 11B, it is necessary to select conditions with which the impurity diffusion layer 120 cannot be penetrated through.

According to further another modification example of the first embodiment, a size relation between the first wirings M1 and the contact holes SL may be selected desirably. FIGS. 5A and 5B show the example in which the diameter of the upper portions of the contact holes SL is larger than the first wiring M1. In spite of this example, the diameter of the upper portion of the contact hole SL may be smaller than the first wiring M1. To the contrary, the diameter of the upper portion of the contact hole SL may be larger than that shown in FIG. 5.

Also, the first wirings M1 may not be provided on the contacts CL. In this case, the contacts CL are provided inside the contact holes SL to penetrate through the first interlayer insulating layer 150.

### Second Embodiment

A second embodiment is different from the first embodiment in that while the contacts with the semiconductor substrate have been described in the first embodiment, contacts according the second embodiment connect a wiring layer on a semiconductor substrate with another wiring layer above the wiring layer. Redundant descriptions on what are similar to or the same as in the first embodiment will be omitted.

Contacts CH, CL and contact holes SH, SL will be used with the same meaning as those in the first embodiment.

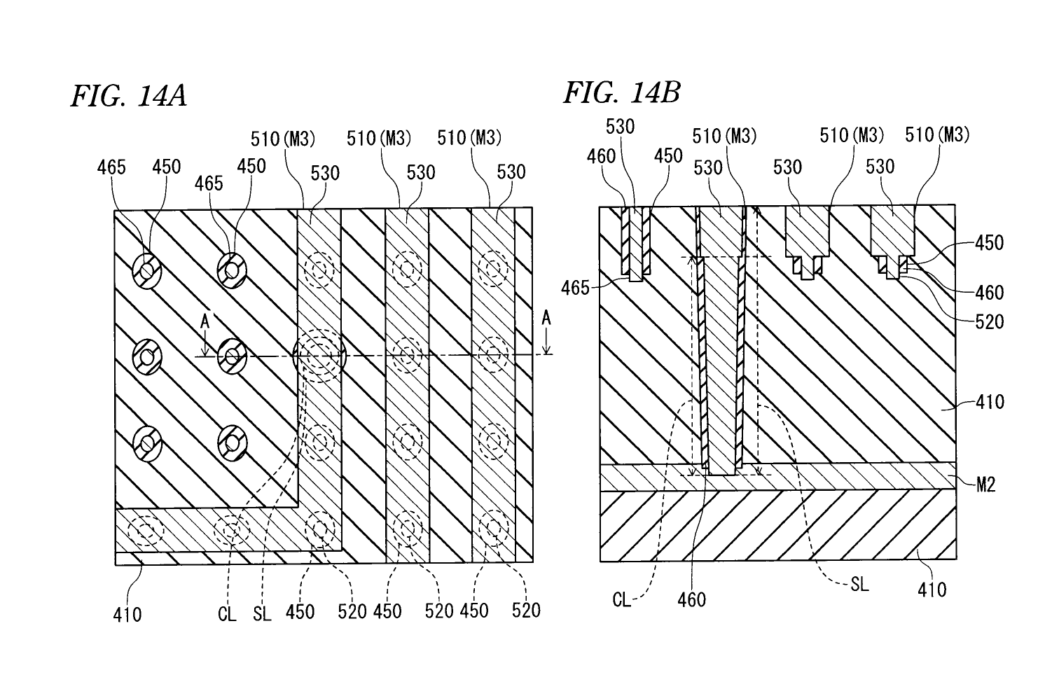

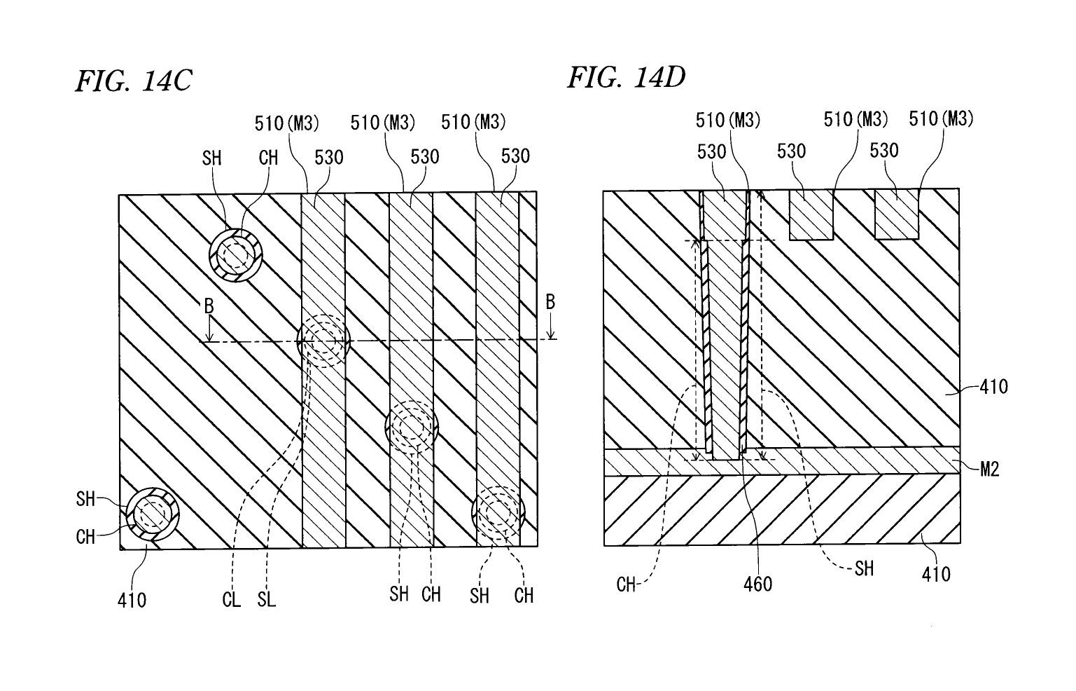

The configuration around a contact CL according to the second embodiment will be described below with reference to FIGS. 14A and 14B.

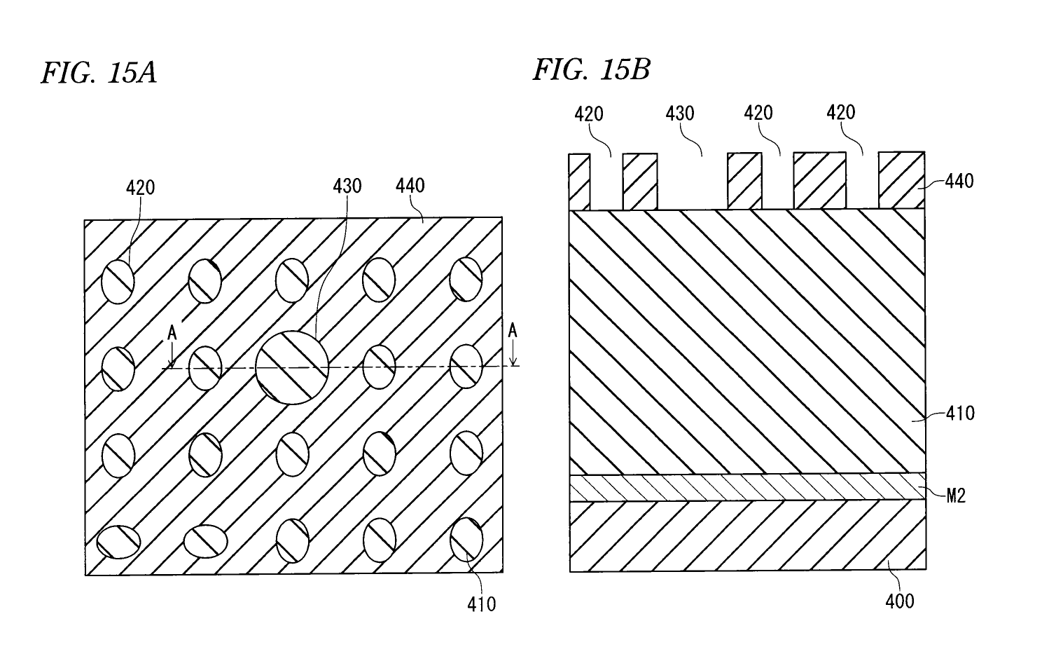

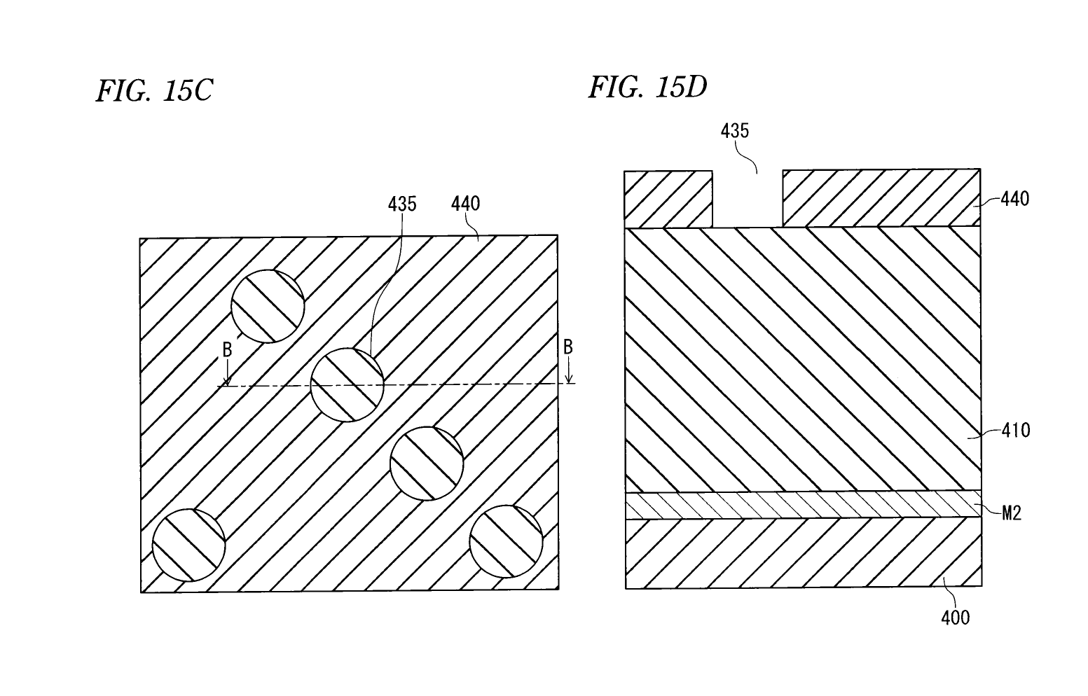

FIG. 14A is an example of a plan view around the contact CL, which is formed sparsely, according to the second embodiment. The structure under a conductive material 530 is also depicted by dotted lines. Also, FIG. 14B is a sectional view taken along a line A-A in FIG. 14A. Without any special notice, the same things can be applied to FIGS. 15A to 22B which will be referred to in the following description.

As shown in FIGS. 14A and 14B, the contact CL and the contact hole SL are disposed substantially at centers of FIGS. 14A and 14B.

The contact hole SL is provided to penetrate through a third interlayer insulating layer 410 and to reach a second wiring (substrate) M2. A spacer film 460 is formed inside the contact hole SL. The contact CL and a third wiring M3 are formed inside the spacer film 460. For example, a silicon oxide film or a silicon nitride film is used as the spacer film 460.

The contact CL is formed inside the contact hole SL. Of the inside of the contact hole SL, an upper portion of the contact CL constitutes a part of the third wiring M3. A conductive material 530 is formed inside the third wiring M3 and the contact CL. The third wiring M3 is in electric conduction with the second wiring M2 through the contact CL.

Also, as shown in FIG. 14A, the third wirings M3 and dummy holes (second holes) 450 are disposed around the contact CL. The third wirings M3 and the dummy holes 450 are disposed in the following manner. Wiring pitches of the third wirings M3 in an X direction (in the right and left directions on the sheet of FIG. 14A) are substantially equal to those of the dummy holes 450 in the X direction. Wiring pitches of the third wirings M3 in a Y direction (in the upper and lower directions on the sheet of FIG. 14A) are substantially equal to those of the dummy holes 450 in the Y direction. The wiring pitches of the dummy holes 450 in the X direction may be substantially equal to those of the dummy holes 450 in the Y direction.

In each third wiring M3, a conductive material 530 is formed inside a third wiring trench 510. The contact CL or an anchor recess portion 520 is provided in a bottom portion of each third wiring trench 510 as will be described later. For example, titanium, tantalum, titanium nitride, tantalum nitride, tungsten, silicon, copper or a laminate of these is used as the conductive material 530.

Each dummy hole 450 is formed with a depth down to a middle of the third interlayer insulating layer 410. Of the dummy holes 450, some dummy holes 450 are provided in areas where the third wirings M3 are formed, and the other dummy holes 450 are provided independently.

The dummy holes 450 provided in the areas where the third wirings M3 are formed are provided in the bottom portions of the third wiring trenches 510. A spacer film 460 is formed inside each dummy hole 450. The anchor recess portion (first recess portion) 520 is disposed inside the spacer film 460.

The anchor recess portion 520 is provided inside the dummy hole 450 and in a bottom portion of the third wiring trench 510. The anchor recess portion 520 is a recess portion that is provided in the third interlayer insulating layer 410. The anchor recess portion 520 has such a depth that the anchor recess portion 520 does not reach the second wiring layer M2. The conductive material 530 is formed inside the anchor recess portion 520. To say in other words, the third wiring trench 510 includes the anchor recess portion 520 in its lower portion, and the conductive material 530 is formed in the third wiring trench 510 including the anchor recess portion 520.

A dummy recess portion (second recess portion) 465 is disposed under each dummy hole 450 which is provided independently.

The spacer film 460 is formed inside the dummy hole 450. The dummy recess portion 465 is formed inside the spacer film 460 and in a bottom portion thereof. The conductive material 530 is formed inside the spacer film 460 and in the dummy recess portion 465.

The configuration around the contacts CH according to the second embodiment will be described below with reference to FIGS. 14C and 14D.

FIG. 14C is a plan view around the contact holes SH and the contacts CH which are densely formed. It is noted that FIG. 14C shows the structure below the conductive material 530 by dotted lines. FIG. 14D is a sectional view taken along a line B-B in FIG. 14C.

As shown in FIG. 14C, the contacts CH are arranged more densely than the contact CL is arranged as shown in FIG. 14A.

The wiring trenches 530 around the contacts CH are not formed with anchor recess portions 520 in lower portions thereof (see FIGS. 14C and 14D).

As shown in FIG. 14D, the contact holes SH are formed so as to penetrate through the third interlayer insulating layer 410 and to reach the second wiring layer M2. The contact holes SH have similar structures to the structure of the contact hole SL.

The contacts CH have similar structures to the structure of the contact CL. The contacts CH are formed inside the respective contact holes SH. Of the inside of the contact holes SH, upper portions of the contacts CH constitute a part of the third wirings M3. The conductive material 530 is formed inside the third wirings M3 and the contacts CH. The third wirings M3 are electrically connects the second wirings M2 through the contacts CH.

It is not necessary for the third wirings M3 to be formed in the upper portions of the contact holes SH as shown in FIGS. 14C and 14D. Where the third wirings M3 are not formed in the upper portions of the contact holes SH, the contacts CH are formed in the entire contact holes SH.

Referring back to FIGS. 14A and 14B, the dummy holes 450 in an area where the contact hole SL is formed are disposed in a grid manner. The grid interval is typically a minimum distance between the contacts CH disposed densely or a constant multiple of the minimum distance. However, the grid interval may be a desired distance which is equal to or larger than the minimum distance.

A manufacturing method according to the second embodiment will be described below with reference to FIGS. 15A to 22D.

First, as shown in FIGS. 15A to 15D, a second interlayer insulating layer 400 and the second wiring M2 (which are an example of a base body) are formed after transistors, wirings, etc. are formed. Titanium, tantalum, titanium nitride, tantalum nitride, tungsten, aluminum, copper or a laminate of these is used for the second wirings M2.

Thereafter, the third interlayer insulating layer 410 is formed to cover the second wiring M2. A mask pattern 440 is formed on the third interlayer insulating layer 410 by a lithography method.

Mask holes 435 which will be used to process dense contact holes SH (may be simply referred to as “mask hole 435”), mask holes 430 which will be used to process sparse contact holes SL (may be simply referred to as “mask holes 430”), and dummy mask holes 420 which will be used to form dummy holes (may be simply referred to as “dummy mask holes 420”) are formed in the mask pattern 440.

Specifically, as shown in FIG. 15A, the dummy mask holes 420 are formed adjacent to the mask holes 430. It is desirable that the dummy mask holes 420 are disposed so that longitudinal directions of the dummy mask holes 420 are parallel to a direction in which the third wiring trenches 510 extend (which will be described later). The dummy mask hole 420 may be disposed to be not in parallel to the third wiring trench 510 but in a desired direction. As shown in FIG. 15C, no dummy mask holes 420 are formed around the mask holes 435. Also, the mask holes 435 are disposed more densely than the mask holes 430 are disposed.

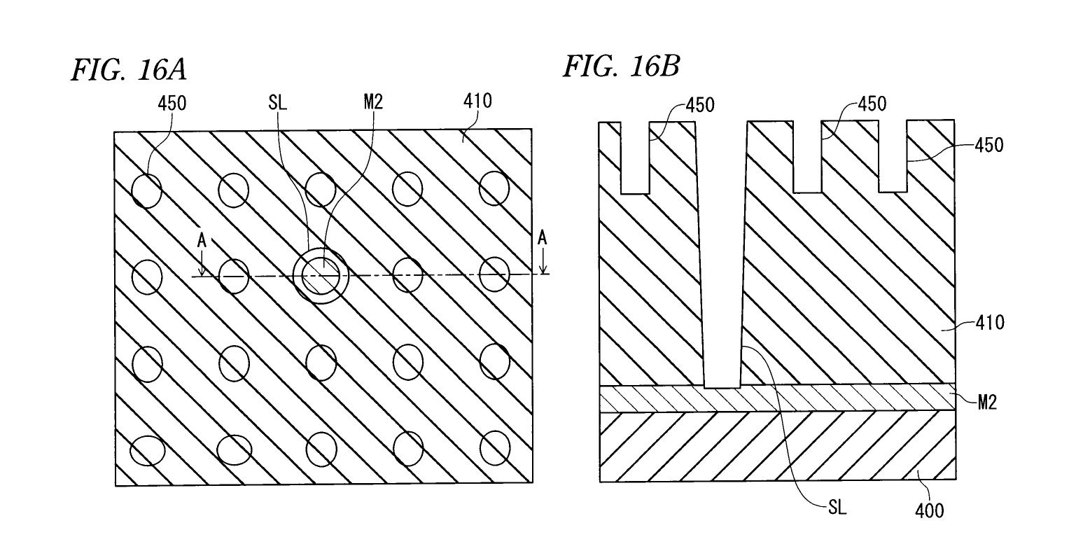

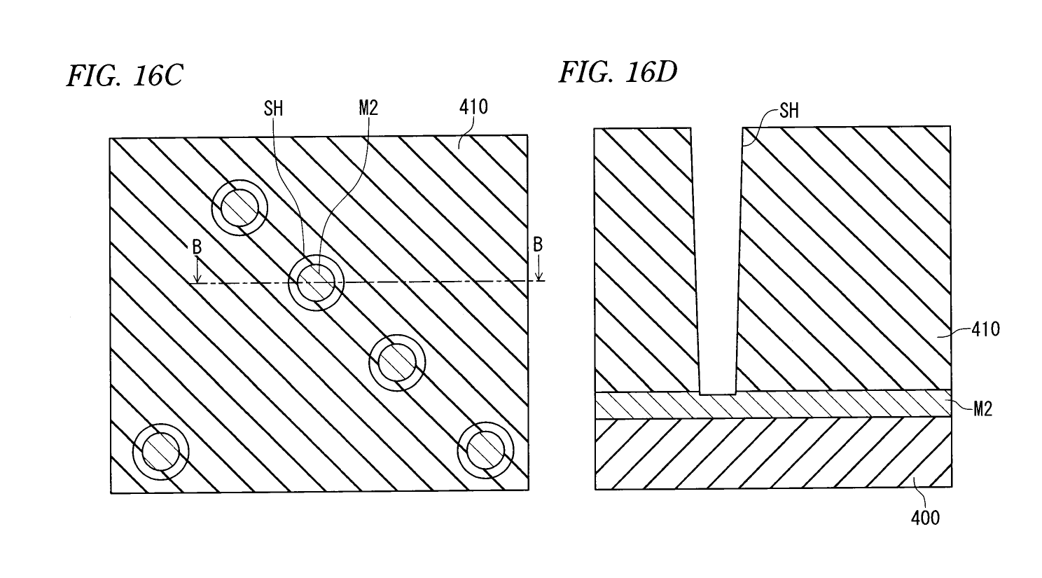

Next, as shown in FIGS. 16A to 16D, the third interlayer insulating layer 410 is processed by RIE using the mask pattern 440 as a mask. Thereafter, the mask pattern 440 is removed.

As a result, the dense contact holes SH, the sparse contact holes SL and the dummy holes 450 are formed. The dense contact holes SH and the sparse contact holes SL reach the second wiring M2.

Here, conditions with which a certain selection ratio between the third interlayer insulating layer 410 and the second wiring M2 can be secured are used so that the etching can be stopped in the second wiring M2.

Also, the etching is stopped in a middle of the third interlayer insulating layer 410 so that the dummy holes 450 cannot reach the second wirings M2. This is due to the micro-loading effect based on aspect ratio, which has been described in the first embodiment.

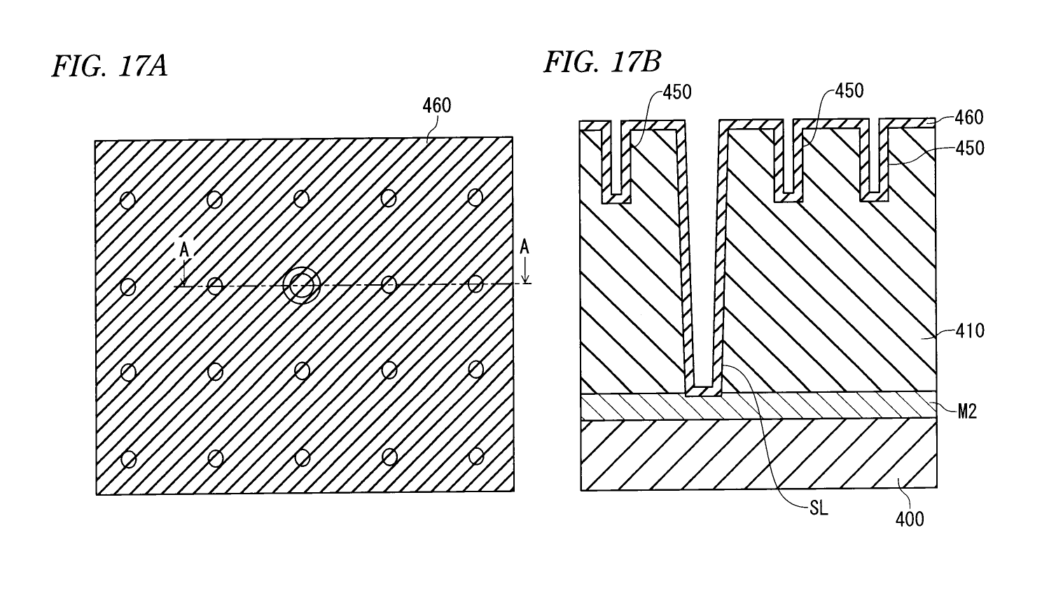

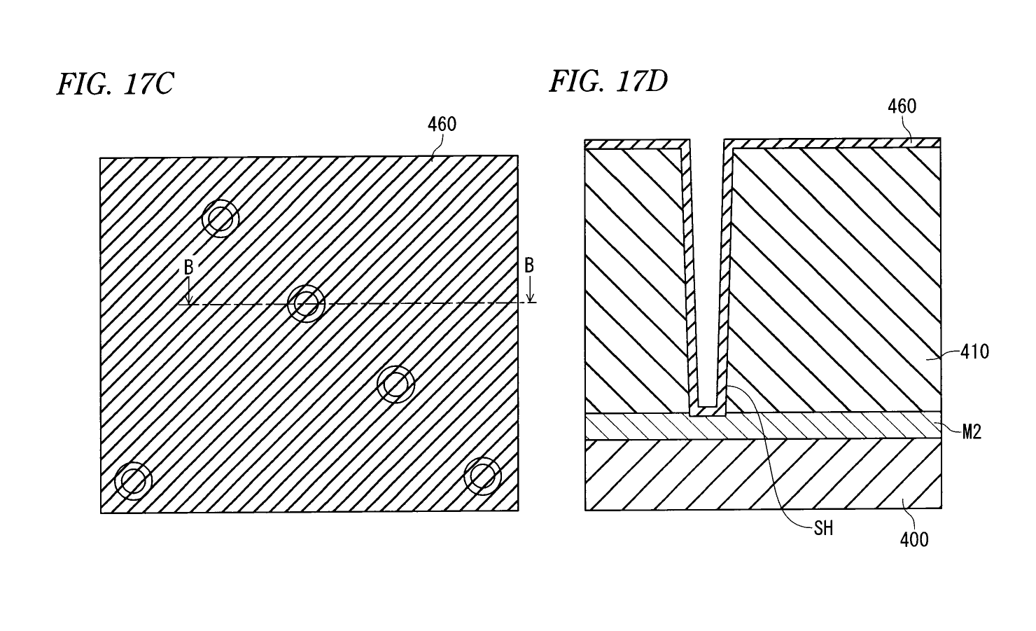

Next, as shown in FIGS. 17A 17D, the spacer film 460 is formed. Due to the spacer film 460, reduction of the inner diameter of the contact holes SL, SH can shrink the semiconductor device. For example, a silicon oxide film or a silicon nitride film is used as the spacer film 460. A film formation method superior in coverage may be used as a method for forming the spacer film 460. For example, a low-pressure CVD method, an ALD method, or the like, may be used.

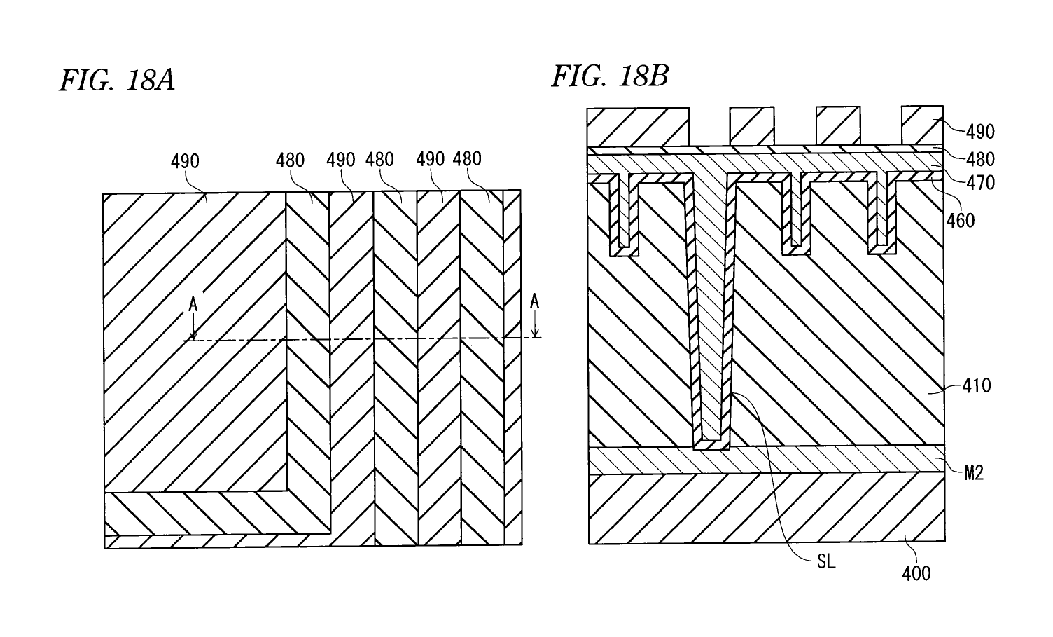

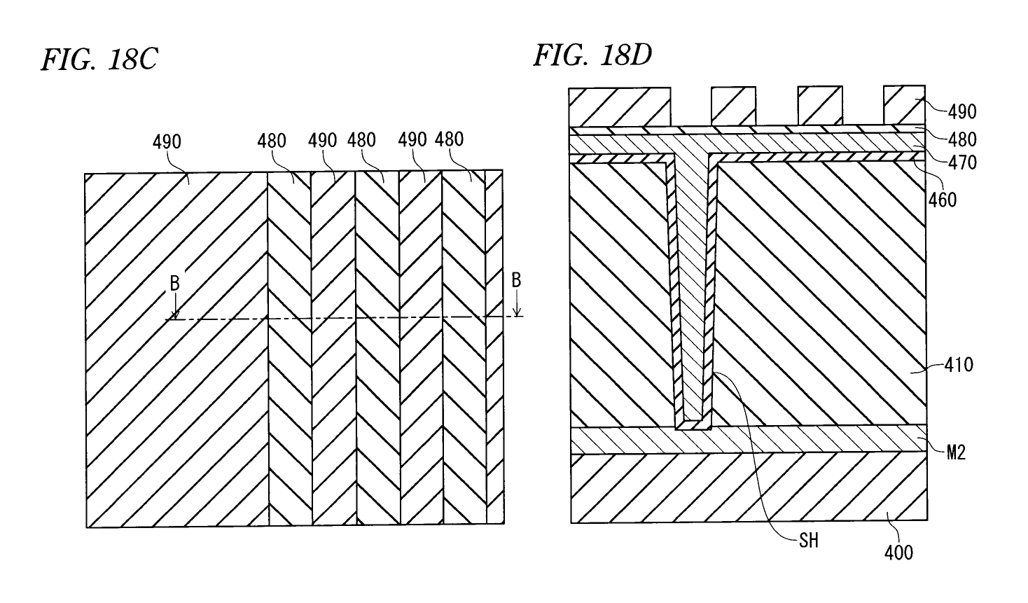

Next, as shown in FIGS. 18A to 18D, a first resist material 470 and a silicon oxide film 480 are formed. Thereafter, a mask pattern 490 using a second resist material is formed by a lithography method.

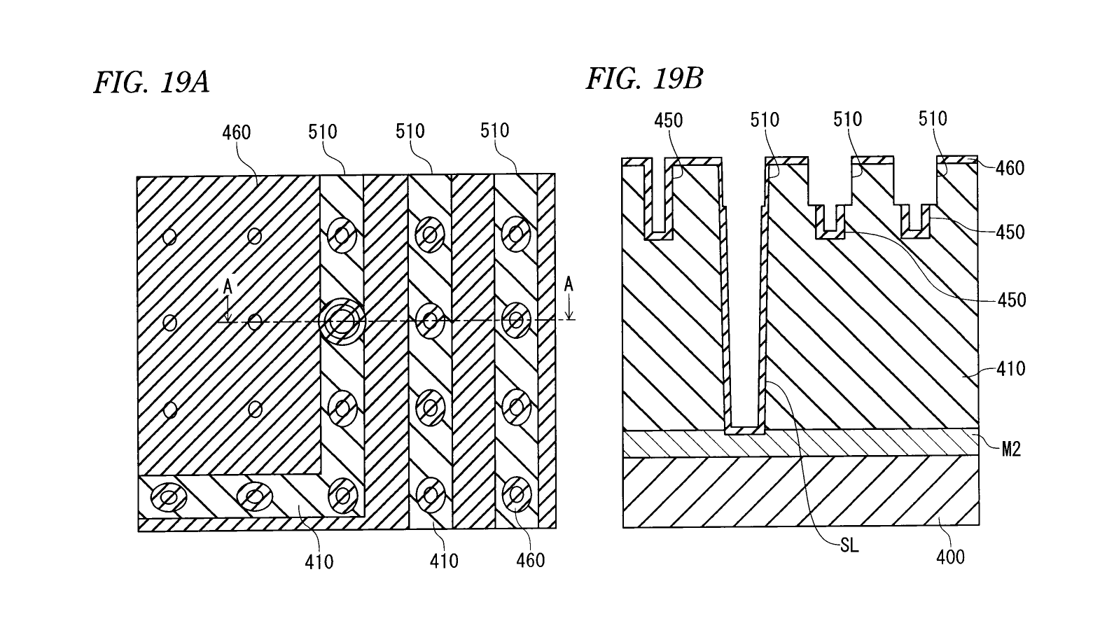

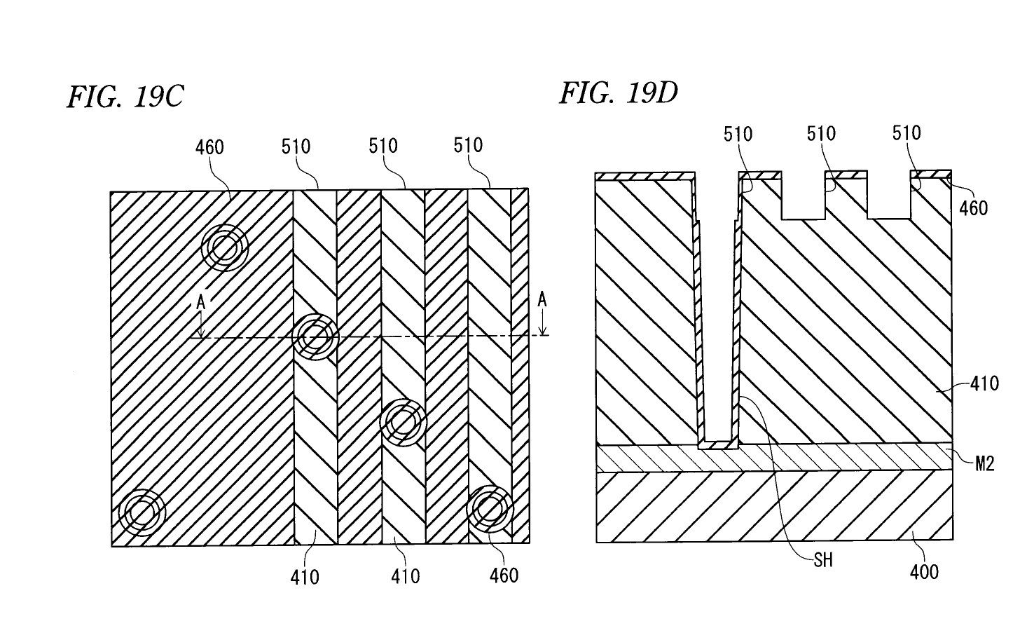

Next, as shown in FIGS. 19A to 19D, the third wiring trenches 510 are formed. The silicon oxide film 480 and the first resist material 470 are etched using the mask pattern 490 as a mask. Thereafter, the spacer film 460 and the third interlayer insulating layer 410 are etched using the silicon oxide film 480 and the first resist material 470 as mask materials. Subsequently, the first resist material 470 is removed.

Due to the etching process, the third wiring trenches 510 are formed on a part of the dummy holes 450 around the contact hole SL. To say in other words, a part of the dummy holes 450 are provided in bottom portions of the third wiring trenches 510. Also, the third wiring trenches 510 are formed in a region where the dense contacts (contact holes SL) are disposed (see FIGS. 19C and 19D).

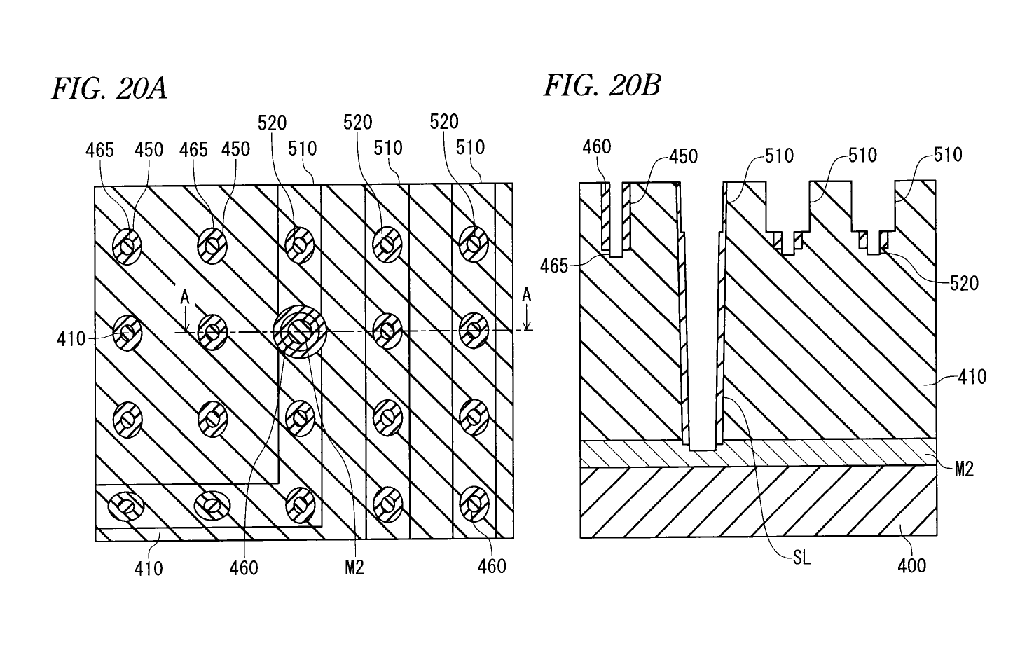

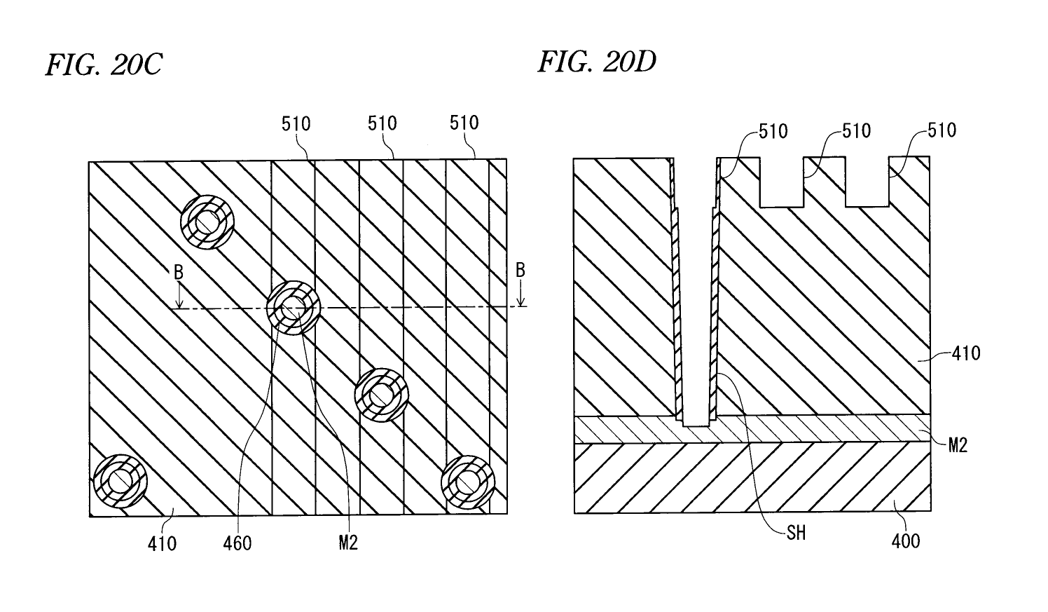

Next, as shown in FIGS. 20A to 20D, all the surface is etched back by RIE. Due to the etching-back treatment, the spacer film 460 is removed from the lower portion of the contact holes SL, SH. Due to the etching-back treatment, the sparse contact holes SL and the dense contact holes SH reach the second wirings M2. Here, it is desirable to perform the etching-back treatment to prevent the sparse contact holes SL and the dense contact holes SH from penetrating through the second wirings M2.

Due to the above described treatment, the spacer film 460 and the third interlayer insulating layer 410 in the bottom surface are etched within areas where the spacer film 460 is formed on the side walls of the dummy holes 450. Due to the etching process, a dummy recess portion 465 is formed in a lower portion of each of the independent dummy holes 450. On the other hand, an anchor recess portion 520 is formed in a lower portion of each of the dummy holes 450 in the areas where the third wiring trenches 510 are formed. To say in other words, each third wiring trench 510 around the sparse contact hole SL (in the region where the sparse contacts are formed) includes the anchor recess portion 520 in its bottom portion. On the other hand, no anchor recess portions 520 are formed in the third wiring trenches 510 around the dense contact holes SH (in the region where the dense contacts are formed).

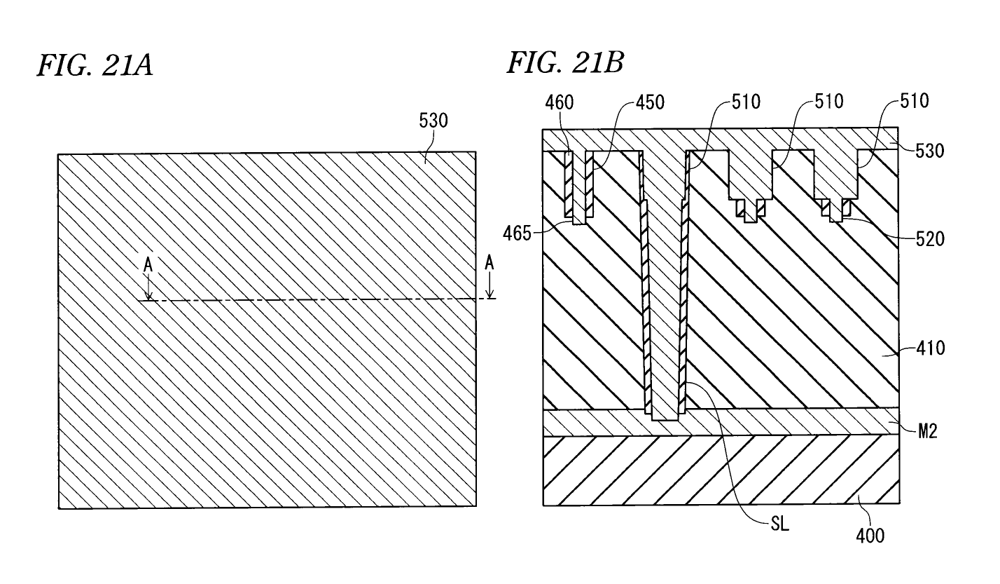

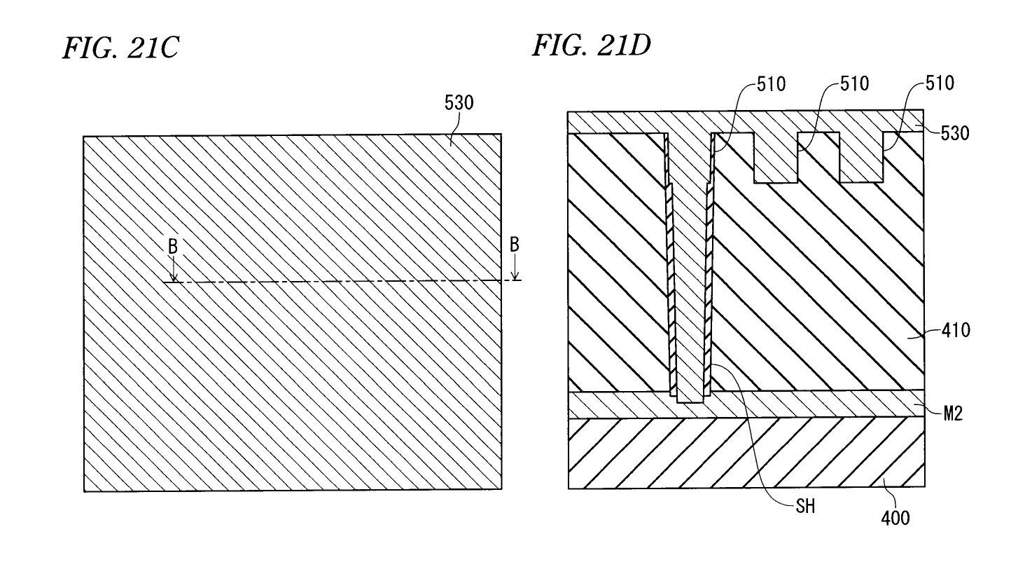

Next, as shown in FIGS. 21A to 21D, the conductive material 530 is formed. The third wiring trenches 510, the inside of the spacer film 460 in the dummy holes 450, the inside of the spacer film 460 in the contact holes SL, SH, the dummy recess portions 465, the anchor recess portions 520, etc., are filled with the conductive material 530.

For example, the conductive material 530 includes a barrier metal layer and a metal layer. For example, titanium, tantalum, titanium nitride, tantalum nitride or a lamination of these is used for the barrier metal layer. Tungsten, copper or the like is used for the metal layer. As a film formation method, a plasma CVD method, a metal plating method, a sputtering method, etc. is used in accordance with the material.

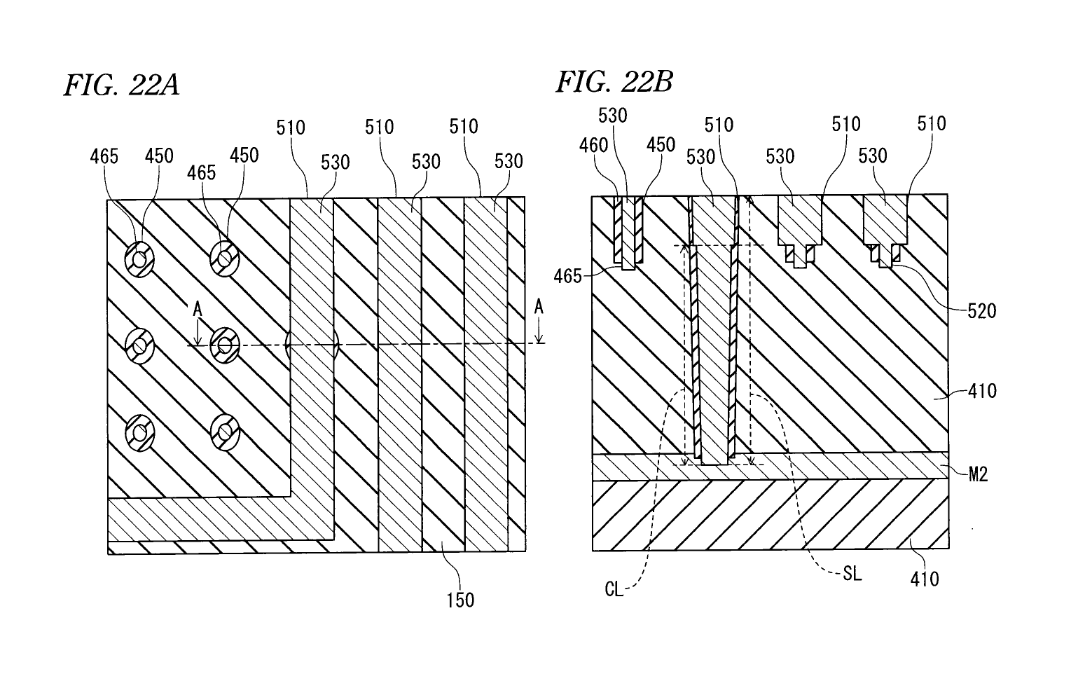

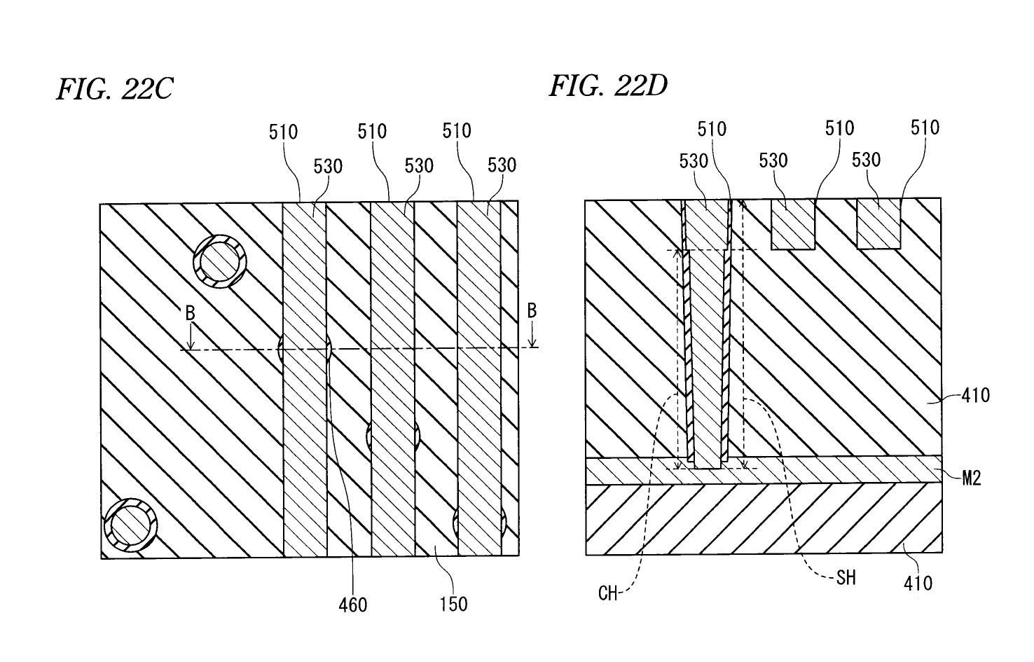

Next, as shown in FIGS. 22A to 22D, flattening is performed by CMP processing until the third interlayer insulating film 410 is exposed. Due to the CMP processing, the third wirings M3 are formed. Also, the contacts CL are formed inside the contact holes SL and in the bottom portions of the third wirings M3. The contacts CH are formed inside the contact holes SH and in the bottom portions of the third wirings M3.

Thereafter, various wiring layers and circuit elements are formed using general manufacturing methods. Accordingly, the semiconductor device according to the second embodiment is manufactured.

As described above, similar advantages to those in the first embodiment can be obtained if the dummy holes 450 are disposed around the sparse contact holes SL.

The first advantage is that the mask holes 430 can be formed easily by the lithography method. The second advantage is that the dense contact holes SH and the sparse contact holes SL can be simultaneously processed easily by RIE. Furthermore, the third advantage is that the adhesion property of the third wirings M3 can be improved.

According to a modification example of the second embodiment, the spacer film 460 may not be provided.

According to another modification example of the second embodiment, a stopper film may be provided on the second wirings M2. Specifically, etching the contact holes SL, SH in FIGS. 16A to 16D is stopped in the stopper film. The stopper film may be processed at the same time as the spacer film 460 shown in FIGS. 20A to 20D is etched.

According to further another modification example of the second embodiment, a size relationship between the third wirings M3 and the contact holes SL may be selected desirably. FIGS. 14A and 14B show the example in which the diameter of an upper portion of each contact hole SL is larger than the third wiring M3. In spite of this example, the diameter of the upper portion of the contact hole SL may be smaller than the third wiring M3. On the contrary, the diameter of the upper portion of the contact hole SL may be larger than the diameter shown in FIGS. 14A and 14B.

Also, the third wirings M3 may not be provided on the contacts CL. In this case, the contacts CL, CH are provided inside the contact holes SL, SH so as to penetrate through the third interlayer insulating layer 410.

A couple of embodiments of the invention have been described. The embodiments are not intended to limit the scope of the invention but are presented just as examples. Those novel embodiments can be carried out in various manners, and various omissions, replacements or changes may be made without departing from the gist of the invention. The embodiments and their modification examples are included in the scope or gist of the invention, and included in the invention recited in the claims and in the scope of its equivalent.

What is claimed is:

1. A semiconductor device comprising:
a base body;
an insulating layer disposed above the based body;
first contacts disposed in the insulating layer, the first contacts being in contact with the base body; and
a first wiring disposed around the first contacts, the first wiring having a lower height than the first contacts have, wherein
the first wiring includes convex portions in a part of a bottom portion thereof.

2. The device of claim 1, wherein
a density at which ones of the first contacts are disposed in a first area is lower than that at which other ones of the first contacts are disposed in a second area, and
the convex portions are disposed only in the first area.

3. The device of claim 2, wherein
the first contacts and the convex portions in the first area are arranged in first and second directions in a matrix manner,
first and second directions crossing each other are defined on a surface of the base body, and
pitches of centers of the first contacts in the first direction and pitches of centers of the convex portions in the first direction are substantially equal to each other.

4. The device of claim 3, wherein
at least two first wirings are disposed as the first wiring, and
a distance between center lines of the first wirings is substantially equal to the pitch of the centers of the first contacts and the pitch of the centers of the convex portions.

5. The device of claim 1, wherein longitudinal directions of the convex portions are substantially parallel to a direction in which the first wiring extends.

6. The device of claim 2, wherein dummy holes are disposed in the insulating layer and around the ones of the first contacts.

7. The device of claim 1, wherein the base body includes a semiconductor substrate.

8. The device of claim 1, wherein the base body includes a second wiring.

9. The device of claim 1, wherein bottom portions of the first contacts are in contact with the base body.

10. The device of claim 2, wherein each of the other ones of the first contacts has about 40 nm to about 60 nm in diameter of an upper portion thereof.

11. The device of claim 6, wherein
each of the dummy holes has an oval shape in a plan view, and
an upper portion of each of the dummy holes has about 30 nm to about 50 nm in a long axis direction and about 10 nm to about 20 nm in a short axis direction.

12. The device of claim 1, further comprising:
third wirings on the first contacts, wherein
an upper surface of the first wiring and upper surfaces of the third wirings are at substantially the same level.

13. A method for manufacturing a semiconductor device, the method comprising:
forming an insulating layer above a base body;
forming first holes in the insulating layer so that the first holes reach the base body;
forming a plurality of second holes around the first holes, the second holes being shallower than the first holes;
forming a trench along a part of the second holes, the trench having a depth reaching a middle of the insulating layer; and
forming a recess portion in a part of a bottom portion of the trench.

14. The method of claim 13, wherein the forming the recess portion includes forming recess portions inside the second hole.

15. The method of claim 13, wherein
the forming the first holes includes
forming a first area including ones of the first holes, and
forming a second area including other ones of the first holes, a density at which the ones of the first holes are disposed in the first area being lower than that at which the other ones of the first holes are disposed in the second area, and
the forming the second holes includes forming the second holes only in the first area.

16. The method of claim 13, wherein
the forming the trench include forming at least two trenches, and
a distance between centers of the trenches is substantially equal to a pitch of centers of the first hole and a pitch of centers of the second holes.

17. The method of claim 13, wherein longitudinal directions of the recess portions are substantially parallel to a direction in which the trench extends.
